(19) United States
(12) Patent Application Publication
(10) Pub. No.: US 2024/0141227 A1
(43) Pub. Date: May 2, 2024

(54) LIGHT-EMITTING ELEMENT, DISPLAY DEVICE, METHOD FOR MANUFACTURING LIGHT-EMITTING ELEMENT, METHOD FOR MANUFACTURING DISPLAY DEVICE, METHOD FOR MANUFACTURING QUANTUM DOT COLLOIDAL SOLUTION, AND QUANTUM DOT COLLOIDAL SOLUTION

(71) Applicant: SHARP KABUSHIKI KAISHA, Sakai City, Osaka (JP)

(72) Inventors: YOSHIHIRO UETA, Sakai City, Osaka (JP); YASUSHI ASAOKA, Sakai City, Osaka (JP); Yuma YAGUCHI, Sakai City, Osaka (JP)

(21) Appl. No.: 18/279,573

(22) PCT Filed: Jun. 28, 2021
(86) PCT No.: PCT/JP2021/024286

§ 371 Date: Aug. 30, 2023

(30) Foreign Application Priority Data
Mar. 30, 2021 (WO) PCT/JP2021/013457

(51) Int. Cl. C09K 11/06; H10K 50/115; H10K 85/30

(52) U.S. Cl. CPC C09K 11/06; H10K 50/115; H10K 85/30

(57) ABSTRACT

A light-emitting element includes a light-emitting layer, wherein the light-emitting layer includes a quantum dot, a halogen element, and a coordination compound that can coordinate to the quantum dot, the coordination compound includes a compound having one or more and n or less (where n is a plural number) carbon-hydrogen bonds, or a compound having n chain structures with different elements bonded at any two coordination positions of an element that can substantially have a coordination number of four or greater, and a mass ratio between the coordination compound and the quantum dot is 0.5 or less.

### TECHNICAL FIELD

The disclosure relates to a light-emitting element, a display device including a plurality of the light-emitting elements, a method for manufacturing a light-emitting element, a method for manufacturing a display device, a method for manufacturing a quantum dot colloidal solution, and a quantum dot colloidal solution.

### BACKGROUND ART

PTL 1 discloses a technique of forming, in a light-emitting element including a light-emitting layer containing quantum dots (semiconductor nanoparticles), a filling material between the quantum dots in order to reduce a leakage current.

There is known a light-emitting element including a quantum dot, with a halogen element bonded to a surface thereof, and a coordination compound that can coordinate to this quantum dot (PTL 2). A fluoride anion is bonded to the surface of the quantum dot, a molar ratio of the fluoride anion to Zn included in the quantum dot is from 0.1 to 0.5, and this molar ratio of the fluoride anion practically reaches a level of being considered part of the composition of the quantum dot. Defects on the quantum dot surface can be inactivated by the fluoride anion bonded to the surface of the quantum dot.

There is known a light-emitting element including a core-shell type quantum dot including a core containing In and P and a shell of one or more layers, a coordination compound that can coordinate to this quantum dot, and a halogen element present at an interface between the core and the shell or in an interior of the shell (PTL 3). A molar ratio of the halogen element to In included in the core of this quantum dot is from 0.80 to 15.00, and this molar ratio of the halogen element practically reaches a level of being considered part of the composition of the quantum dot.

There is known a light-emitting element including a quantum dot light-emitting layer, a hole transport layer, and an electron transport layer, and having a distribution of organic ligands included on the surface of quantum dots present at an interface between the hole transport layer and the quantum dot light-emitting layer and a distribution of organic ligands included on the surface of quantum dots present at an interface between the electron transport layer and the quantum dot light-emitting layer that differ from each other (PTL 4). Therefore, a distribution in the ligand density of this quantum dot is established in a thickness direction of the quantum dot light-emitting layer.

### CITATION LIST

### Patent Literature

PTL 1: JP 2007-95685 A
PTL 2: JP 2020-180278 A
PTL 3: WO 2020/250663 Pamphlet
PTL 4: JP 5175259 B

### SUMMARY

### Technical Problem

The present inventors discovered configurations of a light-emitting element and a display device that further improve characteristics of the light-emitting element.

In the light-emitting element described in PTL 2, defects on the quantum dot surface can be inactivated by the fluoride anion bonded to the surface of the light-emitting element. Then, PTL 2 expresses the view that, as the coordination compound of the quantum dot decreases, luminescence decreases, leading to device deterioration.

The halogen element of the light-emitting element described in PTL 3 is present at the interface between the core and the shell of the quantum dot or in an interior of the shell, and therefore cannot inactivate the defects on the quantum dot surface.

In the light-emitting element described in PTL 4, the ligand density of the quantum dots has a distribution in the thickness direction of the quantum dot light-emitting layer, but a halogen element is not disclosed and thus defects on the quantum dot surface cannot be inactivated.

An aspect of the disclosure is to provide a light-emitting element, a display device, a method for manufacturing a light-emitting element, a method for manufacturing a display device, a method for manufacturing a quantum dot colloidal solution, and a quantum dot colloidal solution that can increase a luminous efficiency.

### Solution to Problem

A light-emitting element according to an aspect of the disclosure includes an anode, a light-emitting layer, and a cathode. The anode, the light-emitting layer, and the cathode are disposed in this order. The light-emitting layer includes a plurality of quantum dots and an insulating material. An average value of a gap between a quantum dot of the plurality of quantum dots in an end face portion of the light-emitting layer on a side of the anode and an end face of the light-emitting layer on the side of the anode is less than an average value of a gap between a quantum dot of the plurality of quantum dots in an end face portion of the light-emitting layer on a side of the cathode and an end face of the light-emitting layer on the side of the cathode.

Further, a method for manufacturing a light-emitting element according to another aspect of the disclosure is a method for manufacturing a light-emitting element including an anode, a light-emitting layer, and a cathode disposed in this order. The method includes forming the anode, forming the light-emitting layer including a plurality of quantum dots and an insulating material, and forming the cathode. The forming the light-emitting layer includes forming a quantum dot material layer including the plurality of quantum dots, and forming an insulating material layer including the insulating material. An average value of a gap between a quantum dot of the plurality of quantum dots in an end face portion of the light-emitting layer on a side of the anode and an end face of the light-emitting layer on the side of the anode is less than an average value of a gap between a quantum dot of the plurality of quantum dots in an end face portion of the light-emitting layer on a side of the cathode and an end face of the light-emitting layer on the side of the cathode.

Further, a display device according to another aspect of the disclosure includes a substrate, a plurality of light-emitting elements disposed on a subpixel-by-subpixel basis on the substrate, and a bank separating the plurality of light-emitting elements on a subpixel-by-subpixel basis. Each of the plurality of light-emitting elements includes an anode, a light-emitting layer, and a cathode disposed in this order. The light-emitting layer includes a main light-emitting portion including a light-emitting material, and an outer edge portion disposed at a position surrounding the main light-emitting portion in plan view of the substrate, and including a deactivation material in which the light-emitting material is deactivated. The bank includes a forwardly tapered face on a side surface, and is in contact with the outer edge portion at the forwardly tapered face.

Further, a method for manufacturing a display device according to another aspect of the disclosure is a method for manufacturing a display device including a plurality of light-emitting elements formed on a substrate on a subpixel-by-subpixel basis, the plurality of light-emitting elements each including an anode, a light-emitting layer, and a cathode disposed in this order. The method includes, in this order, forming, on the substrate, a bank separating the plurality of light-emitting elements on a subpixel-by-subpixel basis and being in contact with the light-emitting layer, forming a light-emitting material layer including a light-emitting material of the light-emitting layer, forming a protection layer in an upper layer overlying the light-emitting material layer, and patterning the light-emitting material layer and the protection layer on a subpixel-by-subpixel basis by dry etching or wet etching the light-emitting material layer and the protection layer to form the light-emitting layer. A face of the bank in contact with the light-emitting layer is a forwardly tapered face.

A light-emitting element according to an aspect of the disclosure for solving the problems described above is a light-emitting element including a light-emitting layer. The light-emitting layer includes a quantum dot, a halogen element, and a coordination compound that can coordinate to the quantum dot. The coordination compound includes a compound having one or more and n or less (where n is a plural number) carbon-hydrogen bonds, or a compound having n chain structures with different elements bonded at any two coordination positions of an element that can substantially have a coordination number of four or greater. A mass ratio between the coordination compound and the quantum dot, that is, a “mass of the coordination compound in a predetermined volume” divided by a “mass of the quantum dot in the predetermined volume”, is 0.5 or less.

A method for manufacturing a quantum dot colloidal solution according to an aspect of the disclosure for solving the problems described above includes adding a halogen element at or near a surface of a quantum dot, causing a coordination compound to coordinate to the surface of the quantum dot, with a mass ratio between the coordination compound and the quantum dot being 0.5 or less, and dispersing the quantum dot with the halogen element added and the coordination compound coordinated into a solvent to obtain a quantum dot colloidal solution.

A method for manufacturing a light-emitting element according to an aspect of the disclosure for solving the problems described above includes forming a quantum dot layer on a first charge transport layer by using a quantum dot colloidal solution manufactured by the method for manufacturing a quantum dot colloidal solution according to an aspect of the disclosure, removing an excess ligand by applying a solvent to the quantum dot layer after the forming the quantum dot layer, and performing heat treatment on the quantum dot layer with the excess ligand removed.

A quantum dot colloidal solution according to an aspect of the disclosure for solving the problems described above includes a quantum dot, a halogen element, a coordination compound that can coordinate to the quantum dot, and a solvent in which the quantum dot, the halogen element, and the coordination compound are dispersed. The coordination compound includes a compound having one or more and n or less (where n is a plural number) carbon-hydrogen bonds, or a compound having n chain structures with different elements bonded at any two coordination positions of an element that can substantially have a coordination number of four or greater. A mass ratio between the coordination compound and the quantum dot is 0.5 or less.

### Advantageous Effects of Disclosure

According to an aspect of the disclosure, it is possible to improve characteristics of a light-emitting element and improve a display quality or a lifetime of a display device including the light-emitting element.

According to an aspect of the disclosure, it is possible to provide a light-emitting element, a method for manufacturing a quantum dot colloidal solution, a method for manufacturing a light-emitting element, and a quantum dot colloidal solution that can increase a luminous efficiency.

### BRIEF DESCRIPTION OF DRAWINGS

FIG. 1 is a schematic view illustrating a side cross section of a display device according to a first embodiment, and an enlarged schematic view of the side cross section in the vicinity of a light-emitting layer.

FIG. 2 is a schematic view of the display device according to the first embodiment, in plan view.

FIG. 3 is an enlarged schematic view of the vicinity of a certain pixel of the display device according to the first embodiment, in plan view.

FIG. 4 is an enlarged schematic view of the side cross section of the display device according to the first embodiment, in the vicinity of a bank and the light-emitting layer.

FIG. 5 is a schematic view for illustrating, by comparison with a light-emitting element according to a comparative embodiment, a mechanism for reducing a reactive current realized by the light-emitting element according to the first embodiment.

FIG. 6 is a graph showing a relationship between a reactive current and an external quantum efficiency of the light-emitting element according to the comparative embodiment.

FIG. 7 is a flowchart for describing a method for manufacturing the display device according to the first embodiment.

FIG. 8 is a flowchart for describing a method for forming the light-emitting layer of the light-emitting element according to the first embodiment.

FIG. 9 illustrates schematic process cross-sectional views for describing the method for forming the light-emitting layer of the light-emitting element according to the first embodiment.

FIG. 10 is an enlarged schematic view of a side cross section of the display device according to a second embodiment, in the vicinity of the light-emitting layer.

FIG. 11 is a flowchart for describing a method for forming the light-emitting layer of a light-emitting element according to the second embodiment.

FIG. 12 illustrates schematic process cross-sectional views for describing the method for forming the light-emitting layer of the light-emitting element according to the second embodiment.

FIG. 13 is an enlarged schematic view of a side cross section of the display device according to a third embodiment, in the vicinity of the light-emitting layer.

FIG. 14 shows graphs for evaluating characteristics of the light-emitting elements according to the first embodiment and a third embodiment in comparison with characteristics of the light-emitting element according to the comparative embodiment.

FIG. 15 is a flowchart for describing a method for forming the light-emitting layer of the light-emitting element according to the third embodiment.

FIG. 16 is an enlarged schematic view of a side cross section of the display device according to a fourth embodiment, in the vicinity of the light-emitting layer.

FIG. 17 is a flowchart for describing a method for forming the light-emitting layer of the light-emitting element according to the fourth embodiment.

FIG. 18 is an enlarged schematic view of the vicinity of a certain pixel of the display device according to a fifth embodiment, in plan view.

FIG. 19 is a schematic view of a side cross section of the display device according to the fifth embodiment.

FIG. 20 is an enlarged schematic view of the side cross section of the display device according to the fifth embodiment, in the vicinity of the bank and a light-emitting layer.

FIG. 21 is a flowchart for describing a method for forming the light-emitting layer of the light-emitting element according to the fifth embodiment.

FIG. 22 illustrates schematic process cross-sectional views for describing the method for forming the light-emitting layer of the light-emitting element according to the fifth embodiment.

FIG. 23 is a schematic view of a quantum dot included in a light-emitting layer of a light-emitting element according to a sixth embodiment.

FIG. 24 is a graph showing typical electrical characteristics of the light-emitting element and analysis results thereof.

FIG. 25 is a schematic view of a quantum dot according to a comparative example.

FIG. 26 is a schematic view of halogen density, level of quantum dots, and carrier injection.

FIG. 27 is a schematic view of the quantum dot according to another comparative example.

FIG. 28 is a schematic view of the quantum dot according to yet another comparative example.

FIG. 29 is a flowchart illustrating a method for manufacturing a quantum dot colloidal solution obtained by dispersing the quantum dot according to the sixth embodiment in a solvent.

FIG. 30 is a graph showing a procedure for manufacturing the quantum dot colloidal solution described above.

FIG. 31 is a cross-sectional view of the light-emitting layer, a hole transport layer, and an electron transport layer formed in the light-emitting element according to the sixth embodiment.

FIG. 32 is a cross-sectional view of the light-emitting element obtained by discharging excess ligands from the light-emitting layer described above.

FIG. 33 is a graph showing characteristics of the light-emitting element described above.

FIG. 34 is a graph showing other characteristics of the light-emitting element described above.

FIG. 35 is a cross-sectional view of the light-emitting layer, the hole transport layer, and the electron transport layer formed in a light-emitting element according to a comparative example.

FIG. 36 is a graph showing characteristics of the light-emitting element described above.

FIG. 37 is a graph showing other characteristics of the light-emitting element described above.

FIG. 38 is a graph showing characteristics of the light-emitting element including quantum dots according to the other comparative example described above.

FIG. 39 is a graph showing other characteristics of the light-emitting element described above.

FIG. 40 is a view for describing a halogen element present at or near a surface of the quantum dot according to the sixth embodiment.

FIG. 41 is a graph for describing details of electrical characteristics of the light-emitting element according to the sixth embodiment.

FIG. 42 is a graph for describing details of electrical characteristics of the light-emitting element according to the comparative example.

FIG. 43 is a graph for describing details of electrical characteristics of a light-emitting element according to the other comparative example.

FIG. 44 is a graph showing other characteristics of the light-emitting element according to the sixth embodiment and the light-emitting element according to the comparative example.

FIG. 45 is a graph showing characteristics of the light-emitting element obtained by discharging the excess ligands described above.

FIG. 46 is a graph showing other characteristics of the light-emitting element described above.

FIG. 47 is a graph showing characteristics of the light-emitting element according to the comparative example.

FIG. 48 is a graph showing other characteristics of the light-emitting element according to the comparative example.

FIG. 49 is a graph showing characteristics of a light-emitting element according to the other comparative example.

FIG. 50 is a graph showing other characteristics of the light-emitting element according to the other comparative example.

### DESCRIPTION OF EMBODIMENTS

### First Embodiment

### Overview of Display Device

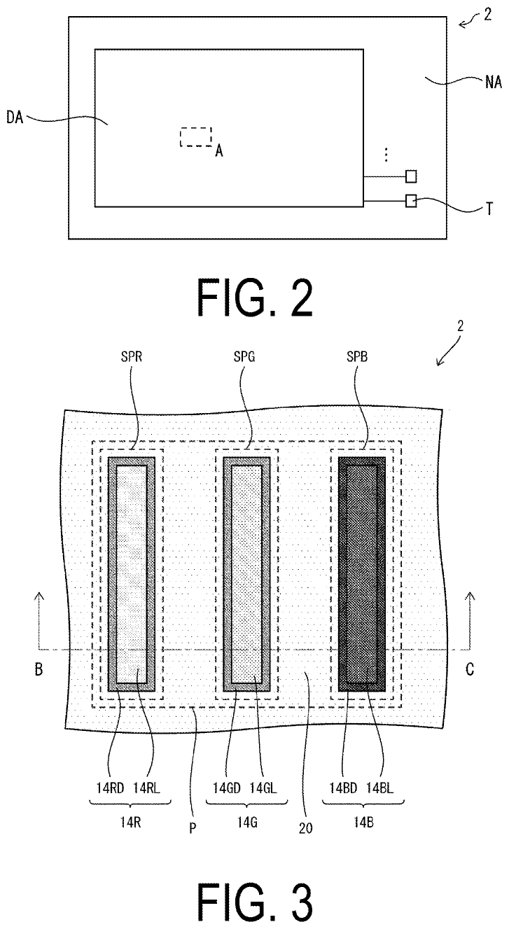

FIG. 2 is a schematic view of a display device 2 according to the present embodiment, in plan view of a substrate 4 described below. As illustrated in FIG. 2, the display device 2 according to the present embodiment includes a display region DA that performs display by the extraction of light emission from subpixels described below, and a frame region NA surrounding a periphery of the display region DA. In the frame region NA, a terminal T into which is input a signal for driving each light-emitting element of the display device 2 is formed.

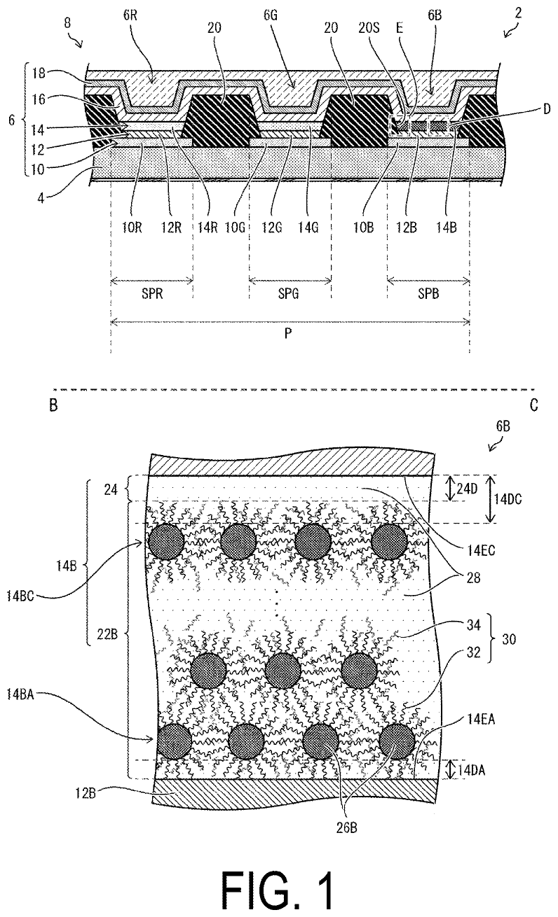

FIG. 3 is an enlarged view illustrating a region A that is a partial region of the display region DA in the schematic view illustrated in FIG. 2. FIG. 1 is a schematic cross-sectional view of the display device 2 according to the present embodiment, and an enlarged schematic view illustrating a partial region of the cross section. The schematic cross-sectional view of the display device 2 illustrated in FIG. 1 is a cross-sectional view taken along an arrow line B-C in FIG. 3. The enlarged schematic view of the display device 2 illustrated in FIG. 1 is an enlarged view of a region D illustrated in FIG. 1. Note that, in FIG. 3, a sealing layer 8, an electron transport layer 16, and a cathode 18, described in detail below, are not illustrated in order to more clearly illustrate pixels and subpixels, described in detail below.

At a position overlapping the display region DA in plan view, the display device 2 according to the present embodiment includes a plurality of pixels. Further, each pixel includes a plurality of subpixels. In the schematic cross-sectional view of the display device 2 illustrated in FIG. 1 and in FIG. 3, a pixel P among the plurality of pixels included in the display device 2 is illustrated. In particular, the pixel P includes a red subpixel SPR, a green subpixel SPG, and a blue subpixel SPB.

The display device 2 according to the present embodiment includes, for example, as illustrated in FIG. 1, the substrate 4, a light-emitting element layer 6 on the substrate 4, and the sealing layer 8 covering the light-emitting element layer 6.

For example, the substrate 4 has a structure obtained by forming thin film transistors (TFTs; not illustrated) on a flexible film substrate including a PET film or the like. Furthermore, the light-emitting element layer 6 and the sealing layer 8 having flexibility are formed on the substrate 4. In this case, the display device 2 according to the present embodiment realizes a flexible display device that can be bent with at least one of the substrate 4 or the sealing layer 8 as an inner side. However, the display device 2 according to the present embodiment is not limited thereto, and may include the substrate 4, the light-emitting element layer 6, or the sealing layer 8 having rigidity.

Note that, in the present specification, a direction from a light-emitting layer 14, described below, of the light-emitting element layer 6 to an anode 10 is referred to as a “downward direction”, and a direction from the light-emitting layer 14 to the cathode 18 is referred to as an “upward direction”.

### Light-Emitting Element

The light-emitting element layer 6 includes the anode 10, a hole transport layer 12, the light-emitting layer 14, the electron transport layer 16, and the cathode 18 in this order from the substrate 4 side. In other words, the light-emitting element layer 6 includes the light-emitting layer 14 between the two electrodes of the anode 10 and the cathode 18. The anode 10 of the light-emitting element layer 6 formed in an upper layer overlying the substrate 4 is formed in an island shape for each subpixel described above, and electrically connected with each of the TFTs of the substrate 4.

In the present embodiment, the light-emitting element layer 6 includes a plurality of light-emitting elements and, in particular, includes one light-emitting element for each subpixel. In the present embodiment, for example, the light-emitting element layer 6 includes, as the light-emitting elements, a red light-emitting element 6R in the red subpixel SPR, a green light-emitting element 6G in the green subpixel SPG, and a blue light-emitting element 6B in the blue subpixel SPB. Hereinafter, in the present specification, unless otherwise specified, “light-emitting element” refers to any one of the red light-emitting element 6R, the green light-emitting element 6G, and the blue light-emitting element 6B included in the light-emitting element layer 6.

Herein, the anode 10, the hole transport layer 12, and the light-emitting layer 14 are individually formed on a subpixel-by-subpixel basis. In particular, in the present embodiment, the anode 10 includes an anode 10R for the red light-emitting element 6R, an anode 10G for the green light-emitting element 6G, and an anode 10B for the blue light-emitting element 6B. Further, the hole transport layer 12 includes a hole transport layer 12R for the red light-emitting element 6R, a hole transport layer 12G for the green light-emitting element 6G, and a hole transport layer 12B for the blue light-emitting element 6B. Furthermore, the light-emitting layer 14 includes a red light-emitting layer 14R that emits red light, a green light-emitting layer 14G that emits green light, and a blue light-emitting layer 14B that emits blue light. On the other hand, the electron transport layer 16 and the cathode 18 are formed in common to the plurality of subpixels.

Accordingly, in the present embodiment, the red light-emitting element 6R is composed of the anode 10R, the hole transport layer 12R, the red light-emitting layer 14R, the electron transport layer 16, and the cathode 18. Further, the green light-emitting element 6G is composed of the anode 10G, the hole transport layer 12G, the green light-emitting layer 14G, the electron transport layer 16, and the cathode 18. Furthermore, the blue light-emitting element 6B is composed of the anode 10B, the hole transport layer 12B, the blue light-emitting layer 14B, the electron transport layer 16, and the cathode 18.

Here, the blue light refers to, for example, light having an emission center wavelength in a wavelength band of equal to or greater than 400 nm and equal to or less than 500 nm. The green light refers to, for example, light having an emission center wavelength in a wavelength band of greater than 500 nm and equal to or less than 600 nm. The red light refers to, for example, light having an emission center wavelength in a wavelength band of greater than 600 nm and equal to or less than 780 nm.

Note that the light-emitting element layer 6 according to the present embodiment is not limited to the configuration described above, and may further include an additional layer between the anode 10 and the cathode 18. For example, the light-emitting element layer 6 may further include a hole injection layer between the anode 10 and the hole transport layer 12. Further, note that the light-emitting element layer 6 may further include an electron injection layer between the electron transport layer 16 and the cathode 18.

The anode 10 and the cathode 18 include conductive materials and are electrically connected to the light-emitting layer 14. The anode 10 is a pixel electrode formed into an island shape on a subpixel-by-subpixel basis, and the cathode 18 is a common electrode formed in common to the plurality of subpixels. For example, of the anode 10 and the cathode 18, the electrode closer to a display surface of the display device 2 is a semitransparent electrode, and the other is a reflective electrode.

The hole transport layer 12 includes a material having hole transport properties, and has a function of transporting holes injected from the anode 10 into the light-emitting layer 14. The hole transport layer 12 may have a function of inhibiting transport of electrons from the light-emitting layer 14 to the anode 10. The electron transport layer 16 includes a material having electron transport properties, and has a function of transporting electrons injected from the cathode 18 into the light-emitting layer 14. The electron transport layer 16 may have a function of inhibiting transport of holes from the light-emitting layer 14 to the cathode 18. The hole transport layer 12 and the electron transport layer 16 transmit at least a portion of the light from each of the light-emitting layers 14.

The light-emitting layer 14 is a layer that emits light as a result of an occurrence of recombination between the holes transported, via the hole transport layer 12, from the anode 10 and the electrons transported, via the electron transport layer 16, from the cathode 18. The light-emitting layer 14 includes a quantum dot material described below as a light-emitting material. As a result, each light-emitting element according to the present embodiment is a quantum dot light-emitting diode (QLED).

Note that the display device 2 according to the present embodiment includes the light-emitting element including the anode 10 on the substrate 4 side, but is not limited thereto. For example, the light-emitting element layer 6 included in the display device 2 according to the present embodiment may include the cathode 18, the electron transport layer 16, the light-emitting layer 14, the hole transport layer 12, and the anode 10 layered in this order from the substrate 4 side. In this case, the cathode 18 is a pixel electrode formed into an island shape on a subpixel-by-subpixel basis, and the anode 10 is a common electrode formed in common to the plurality of subpixels. Further, the electron transport layer 16 may be formed on a subpixel-by-subpixel basis, and the hole transport layer 12 may be formed in common to the plurality of subpixels.

### Bank and Sealing Layer

The display device 2 according to the present embodiment further includes a bank 20 on an upper face of the substrate 4. The bank 20 includes, for example, a coatable resin material including polyimide, and is formed at positions extending across boundaries between subpixels adjacent to each other in plan view. Therefore, the light-emitting element layer 6 is separated into the red light-emitting element 6R, the green light-emitting element 6G, and the blue light-emitting element 6B by the banks 20. Note that, as illustrated in FIG. 1, the bank 20 may be formed at a position covering each peripheral end portion of the anode 10.

For example, the bank 20 includes a coatable photosensitive resin. In particular, in the present embodiment, the bank 20 includes a positive-working photosensitive resin. The banks 20 each include a side surface 20S. Herein, the bank 20 is formed with an area thereof in plan view gradually decreasing in general from the substrate 4 side toward the sealing layer 8 side. Therefore, among the normal directions of the side surfaces 20S, the direction toward an interior side of the bank 20 is more so a direction from the sealing layer 8 toward the substrate 4 than a planar direction of the upper face of the substrate 4 that is the face on which the bank 20 is formed.

When a specific member includes a side surface and the specific member is formed on a specific face, an angle formed by an outer surface side of the side surface and the specific face is an obtuse angle. In this case, the side surface is referred to as a forwardly tapered face in the present specification. For example, in a truncated regular quadrangular pyramid in which an area of a lower base is large compared with an area of an upper base, all side surfaces of the truncated regular quadrangular pyramid are forwardly tapered faces.

In the present embodiment, the bank 20 is formed on the upper face of the substrate 4. Further, an angle formed by an outer surface side of the side surface 20S of the bank 20 and the upper face of the substrate 4 is an obtuse angle. Accordingly, the side surface 20S of the bank 20 is a forwardly tapered face. Therefore, in the present embodiment, with the light-emitting layer of each light-emitting element separated by the bank 20 having the forwardly tapered face on the side surface, the light-emitting layer is in contact with the side surface 20S that is the forwardly tapered face.

The sealing layer 8 covers the light-emitting element layer 6 and the banks 20 and seals each light-emitting element included in the display device 2. The sealing layer 8 reduces permeation of foreign matters including moisture and the like into the light-emitting element layer 6 and the like from outside the display device 2 on the sealing layer 8 side. The sealing layer may have, for example, a layered structure of an inorganic sealing film made of an inorganic material and an organic sealing film made of an organic material. The inorganic sealing film is formed by chemical vapor deposition (CVD) and constituted by a silicon oxide film, a silicon nitride film, a silicon oxynitride film, or a layered film of these, for example. The organic sealing film is constituted by, for example, a coatable resin material including polyimide.

### Quantum Dot and Insulating Material

The light-emitting layer 14 according to the present embodiment will now be described in more detail with reference to an enlarged schematic view in the vicinity of the light-emitting layer 14 illustrated in FIG. 1. In particular, the enlarged schematic view is an enlarged schematic view illustrating the vicinity of the blue light-emitting layer 14B of the blue light-emitting element 6B of the display device 2 according to the present embodiment. Herein, unless otherwise specified, the red light-emitting layer 14R and the green light-emitting layer 14G according to the present embodiment have the same configuration as that of the blue light-emitting layer 14B except for blue quantum dots described below. Note that the enlarged schematic view of FIG. 1 is an enlarged view illustrating a portion of a main light-emitting portion 14BL, described below, of the blue light-emitting layer 14B, in an enlarged manner.

Note that, in the present specification, the term “quantum dot” refers to a particle with an outermost shell having a maximum width of 100 nm or less. A shape of the quantum dot need only be within a range satisfying the maximum width described above, is not particularly limited, and is not limited to a spherical three-dimensional shape, in other words, a circular cross-sectional shape. The quantum dot may have, for example, a polygonal cross-sectional shape, a rod-like three-dimensional shape, a branch-like three-dimensional shape, a three-dimensional shape with unevenness on the outermost surface, or a shape obtained by combining these shapes.

As illustrated in the enlarged schematic view of the vicinity of the blue light-emitting layer 14B in FIG. 1, the blue light-emitting layer 14B includes a blue quantum dot layer 22B and an insulating layer 24 disposed in this order from the hole transport layer 12B side, in other words, the anode 10 side. The blue quantum dot layer 22B includes a plurality of blue quantum dots 26B, an insulating material 28, and a plurality of ligands 30. The insulating layer 24 includes the insulating material 28. In particular, the insulating layer 24 includes only the insulating material 28 among the materials included in the blue quantum dot layer 22B. Note that the insulating layer 24 need not be a layer having a completely uniform film thickness, and may include a portion having a different thickness compared with that of other portions, such as a portion having unevenness on any surface, for example.

The blue quantum dot 26B is a semiconductor nanoparticle that emits blue light by the recombination of holes and electrons injected into the blue light-emitting layer 14B. The blue quantum dot 26B may have, for example, a core-shell structure including a core including a material contributing to light emission and a shell surrounding the core. A material of the blue quantum dot 26B is not particularly limited as long as the material is a semiconductor nanoparticle that emits blue light, and may include a known material used for a quantum dot.

The blue quantum dot layer 22B includes the ligands 30 as a first compound that can be coordinated to the blue quantum dot 26B. The ligand 30 is, for example, a compound including at least, at one end of a carbon chain, a coordination functional group that can form a coordination bond with the blue quantum dot 26B. In the present embodiment, the ligands 30 include a binding ligand 32 that forms a coordination bond with the blue quantum dot 26B as a binding compound, and further include an excess ligand 34 that does not form a coordination bond with the blue quantum dot 26B and is dispersed in the insulating material 28 as an excess compound. The binding ligand 32 and the excess ligand 34 may have the same configuration except for the presence or absence of the coordination bond with the blue quantum dot 26B. The ligand 30 has a function of reducing aggregation of the blue quantum dots 26B, protecting outer surfaces of the blue quantum dots 26B, or the like. The ligand 30 may include, for example, the same material as a known material of a ligand that can be coordinated to a quantum dot.

In general, a ligand bonded to a quantum dot by a coordination bond is bound to the quantum dot by the coordination bond and therefore has a small diffusion coefficient compared with that of a ligand not bonded to a quantum dot and having the same molecular weight. This corresponds to the fact that the free energy of the ligand bonded to the quantum dot is low compared with that of a ligand not bonded to a quantum dot and having the same molecular weight. Accordingly, in the present embodiment, it can be said that the excess ligand 34 is a ligand having a higher free energy relative to molecular weight than the binding ligand 32.

The insulating material 28 is made of a material having a high electrical resistivity and a low carrier mobility compared to those of the material of the blue quantum dot 26B and the material of the ligand 30. The insulating material 28 included in the blue quantum dot layer 22B is filled between the blue quantum dots 26B. Further, in the present embodiment, the insulating material 28 included in the insulating layer 24 and the insulating material 28 included in the blue quantum dot layer 22B may be the same material and may be continuous or separate.

### End Face of Light-Emitting Layer and Structure in Vicinity of End Face

The insulating material 28 constitutes an end face 14EA on the anode 10 side and an end face 14EC on the cathode 18 side of the blue light-emitting layer 14B. Therefore, in the present embodiment, the hole transport layer 12B is in contact with the end face 14EA, and the electron transport layer 16 is in contact with the end face 14EC.

Herein, the blue quantum dot layer 22B includes an end face portion 14BA on the anode 10 side in the vicinity of the end face 14EA, and includes an end face portion 14BC on the cathode 18 side in the vicinity of the end face 14EC. The plurality of blue quantum dots 26B and the plurality of ligands 30 are positioned in the end face portion 14BA and the end face portion 14BC.

Note that, in the present embodiment, the end face portion 14BA refers to, for example, an area of the blue light-emitting layer 14B from the end face 14EA to a portion where 20 blue quantum dots 26B closest to the end face 14EA are positioned. Further, the end face portion 14BC refers to, for example, an area of the blue light-emitting layer 14B from the end face 14EC to a portion where 20 blue quantum dots 26B closest to the end face 14EC are positioned.

At least one of the binding ligand 32 coordinated to the blue quantum dot 26B positioned in the end face portion 14BA or the excess ligand 34 positioned around that blue quantum dot 26B is in contact with an end face of the blue quantum dot layer 22B on the anode 10 side. Accordingly, at least one of the ligands 30 positioned in the end face portion 14BA is in contact with the end face 14EA.

At least one of the binding ligand 32 coordinated to the blue quantum dot 26B positioned in the end face portion 14BC or the excess ligand 34 positioned around that blue quantum dot 26B is in contact with an end face of the blue quantum dot layer 22B on the cathode 18 side. Accordingly, at least one of the ligands 30 positioned in the end face portion 14BC is in contact with the end face 14EC with the insulating layer 24 interposed therebetween.

Note that FIG. 1 illustrates a portion of the ligands 30 positioned in the end face portion 14BA in contact with the end face of the blue quantum dot layer 22B on the anode 10 side, and a portion of the ligands 30 positioned in the end face portion 14BC in contact with the end face of the blue quantum dot layer 22B on the cathode 18 side. However, no such limitation is intended, and at least one of the blue quantum dots 26B positioned in the end face portion 14BA may be in contact with the end face of the blue quantum dot layer 22B on the anode 10 side. Further, at least one of the blue quantum dots 26B positioned in the end face portion 14BC may be in contact with the end face of the blue quantum dot layer 22B on the cathode 18 side.

Here, an average value of a gap between the blue quantum dot 26B in the end face portion 14BA and the end face 14EA is referred to as a gap 14DA, and an average value of a gap between the blue quantum dot 26B in the end face portion 14BC and the end face 14EC is referred to as a gap 14DC. For example, assume for the moment a cross section obtained by cutting the blue light-emitting layer 14B at an arbitrary cross section in the normal direction of any surface of the blue light-emitting layer 14B. In this case, in the present embodiment, the gap 14DA is an average value of the gaps between the end face 14EA and, among the blue quantum dots 26B facing the end face 14EA, 20 blue quantum dots 26B adjacent to each other, on the cut face. Further, the gap 14DC is an average value of the gaps between the end face 14EC and, among the blue quantum dots 26B facing the end face 14EC, 20 blue quantum dots 26B adjacent to each other, on the cut face. Note that, in the present specification, the gap between the blue quantum dot 26B and one end face of the end face 14EA and the end face 14EC is the shortest distance between an outer periphery of the blue quantum dot 26B and the end face, on the cut face described above.

In the present embodiment, the end face of the blue quantum dot layer 22B on the anode 10 side is identical to the end face 14EA and is in contact with the hole transport layer 12B. On the other hand, the end face of the blue quantum dot layer 22B on the cathode 18 side is separated from the end face 14EA due to the insulating layer 24. Therefore, the gap 14DA is smaller than the gap 14DC.

The red light-emitting layer 14R and the green light-emitting layer 14G according to the present embodiment have the same configuration as that of the blue light-emitting layer 14B except for including red quantum dots emitting red light and green quantum dots emitting green light instead of the blue quantum dots 26B, respectively. For example, with a quantum dot having a core-shell structure, a wavelength of light emitted can be controlled by controlling a particle size of the core. Accordingly, the red quantum dot and the green quantum dot may have, for example, the same configuration as that of the blue quantum dot 26B except for the particle size of the core.

### Main Light-Emitting Portion and Outer Edge Portion

As illustrated in FIG. 3, the red light-emitting layer 14R according to the present embodiment includes a main light-emitting portion 14RL and an outer edge portion 14RD. Further, the green light-emitting layer 14G according to the present embodiment includes a main light-emitting portion 14GL and an outer edge portion 14GD. Further, the blue light-emitting layer 14B according to the present embodiment includes the main light-emitting portion 14BL and an outer edge portion 14BD. The outer edge portion 14RD, the outer edge portion 14GD, and the outer edge portion 14BD, in plan view of the substrate 4, are disposed at positions surrounding the main light-emitting portion 14RL, the main light-emitting portion 14GL, and the main light-emitting portion 14BL, respectively.

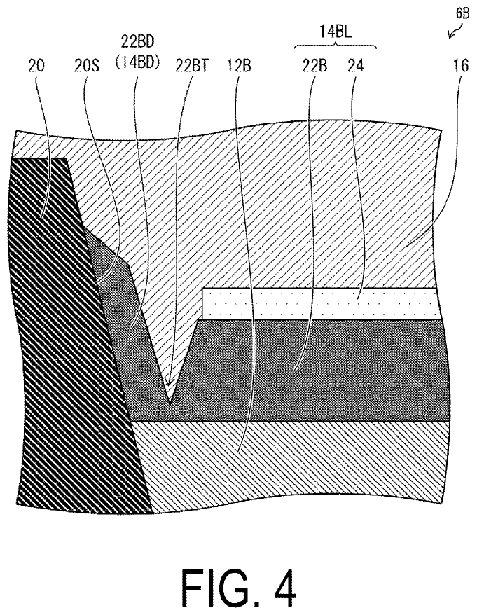

The main light-emitting portion and the outer edge portion of the light-emitting layer 14 according to the present embodiment will now be described in more detail with reference to an enlarged schematic view of the vicinity of an interface between the bank 20 and the light-emitting layer 14 illustrated in FIG. 4. In particular, the enlarged schematic view is an enlarged schematic view illustrating the vicinity of the interface between the bank 20 and the blue light-emitting layer 14B of the blue light-emitting element 6B of the display device 2 according to the present embodiment, and is an enlarged view illustrating a region E illustrated in FIG. 1. Herein, unless otherwise specified, the main light-emitting portion 14RL and the main light-emitting portion 14GL have the same configuration as that of the main light-emitting portion 14BL, and the outer edge portion 14RD and the outer edge portion 14GD have the same configuration as that of the outer edge portion 14BD, except for materials.

The main light-emitting portion 14BL includes the blue quantum dot layer 22B and the insulating layer 24 described above. Therefore, the main light-emitting portion 14BL includes the blue quantum dots 26B that are the light-emitting material included in the blue light-emitting layer 14B. On the other hand, the outer edge portion 14BD includes a deactivation layer 22BD and does not include the insulating layer 24. The deactivation layer 22BD is in contact with the side surface 20S of the bank 20, and is continuous with the blue quantum dot layer 22B of the main light-emitting portion 14BL with a thin film portion 22BT, having a thinner thickness than a surrounding portion, interposed therebetween.

However, the deactivation layer 22BD need not be continuous with the main light-emitting portion 14BL, and may be formed as a separate body. In other words, the blue light-emitting layer 14B may not be formed between the main light-emitting portion 14BL and the outer edge portion 14BD, and the main light-emitting portion 14BL and the outer edge portion 14BD may be separated by the electron transport layer 16.

The deactivation layer 22BD includes a material in which the blue quantum dots 26B have been deactivated by oxidation, moisture permeation, physical damage, or the like. Therefore, the deactivation layer 22BD has a low luminous efficiency compared with that of the blue quantum dot layer 22B. Otherwise, the deactivation layer 22BD may have the same configuration as that of the blue quantum dot layer 22B. Note that the outer edge portion 14RD and the outer edge portion 14GD according to the present embodiment have the same configuration as that of the outer edge portion 14BD except for inclusion of a deactivation layer including a material in which the red quantum dots were deactivated and a deactivation layer including a material in which the green quantum dots were deactivated, respectively. The effect of the deactivation layer 22BD will be described below in detail together with a method for forming the deactivation layer 22BD.

### Reactive Current

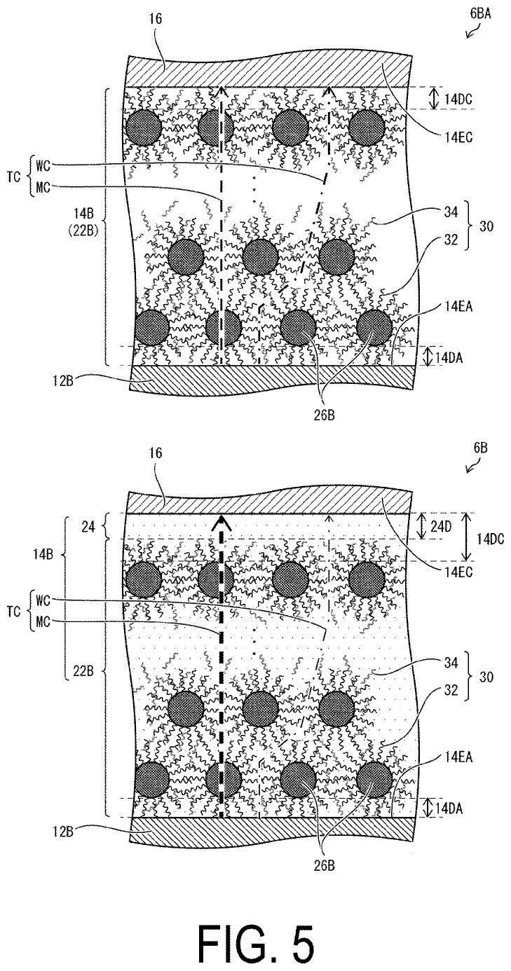

The effect of the blue light-emitting element 6B according to the present embodiment will be described by comparison with a blue light-emitting element 6BA according to a comparative embodiment. FIG. 5 is a diagram illustrating the blue light-emitting element 6B according to the present embodiment together with the blue light-emitting element 6BA according to the comparative embodiment, and is an enlarged schematic view illustrating a position corresponding to the enlarged schematic view of the vicinity of the blue light-emitting layer 14B of the blue light-emitting element 6B illustrated in FIG. 1.

In the blue light-emitting element 6BA according to the comparative embodiment, the blue light-emitting layer 14B does not include the insulating layer 24. Therefore, the end face 14EC of the blue quantum dot layer 22B on the cathode 18 side according to the comparative embodiment is in contact with the electron transport layer 16. Further, the blue quantum dot layer 22B according to the comparative embodiment does not include the insulating material 28. Otherwise, the blue light-emitting element 6BA according to the comparative embodiment has the same configuration as that of the blue light-emitting element 6B according to the present embodiment.

When the blue light-emitting element 6BA according to the comparative embodiment is driven and a potential difference is applied between the anode 10 and the cathode 18, a main current MC and a reactive current WC flow through the blue light-emitting layer 14B as illustrated in FIG. 5. The main current MC mainly flows through the blue quantum dots 26B, while the reactive current WC mainly flows through the binding ligands 32 or the excess ligands 34 around the blue quantum dots 26B.

In general, a reactive current that does not flow through a quantum dot does not contribute to a mechanism for transporting carriers to the quantum dot, and thus does not contribute to the light emission of the quantum dot. Further, a total current TC flowing through the entire blue light-emitting element 6BA is the sum of the main current MC and the reactive current WC. The total current TC does not significantly change as long as the potential difference between the electrodes of the blue light-emitting element 6BA is constant. Further, a power consumption of the blue light-emitting element 6BA depends on the total current TC.

Accordingly, when the reactive current WC is high compared with the main current MC, the current that does not contribute to the light emission of the blue quantum dot 26B increases, decreasing the luminous efficiency of the blue light-emitting element 6BA. Accordingly, an intensity of the light emission extracted from the blue light-emitting element 6BA relative to the power consumed by the blue light-emitting element 6BA is reduced.

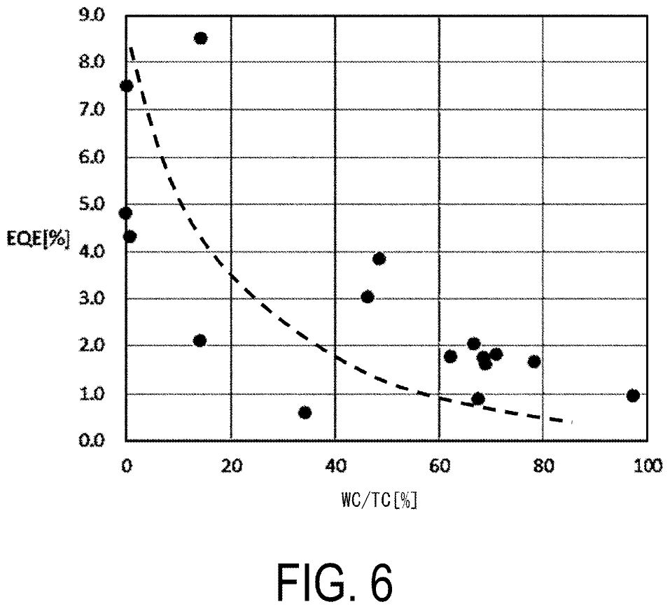

Further, when a ratio of the reactive current to the total current flowing through the light-emitting element is high, an external quantum efficiency of the light-emitting element decreases. FIG. 6 is a graph showing the relationship between the ratio of the reactive current to the total current and the external quantum efficiency of the light-emitting element according to the comparative embodiment. In the graph of FIG. 6, the horizontal axis represents the ratio (unit:percent) of the reactive current to the total current, and the vertical axis represents the external quantum efficiency (unit: percent) of the light-emitting element. FIG. 6 shows plotted data obtained by manufacturing a plurality of light-emitting elements having the same configuration as that of the blue light-emitting element 6BA, driving the light-emitting elements, and measuring the total current, the reactive current, and the external quantum efficiency of each.

The dotted line shown in FIG. 6 is an approximate curve derived from the data plotted in FIG. 6. As is clear from the approximate curve, when the ratio of the reactive current to the total current is high, the external quantum efficiency of the light-emitting element is low.

Some light-emitting elements have a low ratio of reactive current to total current and improved external quantum efficiency, but such light-emitting elements are manufactured by chance due to manufacturing errors in the manufacturing stage of the light-emitting elements. Therefore, in the comparative embodiment, it is difficult to reliably manufacture a light-emitting element having a high external quantum efficiency. Actually, as is clear from FIG. 6, the number of manufactured light-emitting elements having a low ratio of the reactive current to the total current and a high external quantum efficiency is extremely small compared with the number of manufactured light-emitting elements having a high ratio of the reactive current to the total current and a low external quantum efficiency.

Herein, in general, the reactive current WC flowing through the ligands 30 flows in the ligands 30 and between the ligands 30 mainly by hopping conduction. Therefore, the main component of the reactive current WC flowing through the light-emitting layer is proportional to the carrier mobility and the dielectric constant of the materials other than the quantum dots and to the applied voltage, and is inversely proportional to the film thickness of the light-emitting layer.

It is difficult to significantly change a dielectric constant of the light-emitting layer of the light-emitting element, even if the material is replaced. Further, the voltage applied to the light-emitting layer also depends on the intensity of light extracted from the light-emitting element, making it difficult to reduce the applied voltage. On the other hand, when a thickness of the light-emitting layer is excessively increased, a resistance of the entire light-emitting element increases. Accordingly, to reduce the reactive current flowing through the light-emitting layer, it is important to reduce the carrier mobility of the materials other than the quantum dots.

The blue light-emitting layer 14B included in the blue light-emitting element 6B according to the present embodiment includes the insulating material 28. The carrier mobility of the insulating material 28 is lower than the carrier mobility of the ligand 30. Therefore, in the blue light-emitting layer 14B according to the present embodiment, the reactive current WC flowing through the ligand 30 without going through the blue quantum dot 26B can be reduced. With this, the ratio of the reactive current WC to the total current TC decreases, improving the ratio of the main current MC to the total current TC. Accordingly, the blue light-emitting element 6B according to the present embodiment improves in external quantum efficiency and improves in luminous efficiency.

In particular, the blue light-emitting layer 14B included in the blue light-emitting element 6B according to the present embodiment includes the insulating material 28 filled between the blue quantum dots 26B. Therefore, the blue light-emitting layer 14B according to the present embodiment can more efficiently reduce the reactive current WC flowing around the blue quantum dots 26B.

### Other Effects of Light-Emitting Element

Further, in the present embodiment, the gap 14DA of the blue light-emitting layer 14B is smaller than the gap 14DC. As a result, compared with a case in which the gap 14DA and the gap 14DC are equal, the efficiency of electron injection from the electron transport layer 16 into the blue quantum dots 26B is reduced. Therefore, the efficiency of hole injection from the hole transport layer 12B into the blue quantum dot 26B relatively increases compared with the efficiency of electron injection from the electron transport layer 16 to the blue quantum dot 26B.

In general, in an electric field carrier injection type light-emitting element including a quantum dot as a light-emitting material, the injection efficiency of electrons into the light-emitting layer is high compared with the injection efficiency of holes into the light-emitting layer, and an electron excess may occur in the light-emitting layer when the light-emitting element is driven. When an electron excess occurs in the light-emitting layer, the luminous efficiency of the light-emitting element may decrease and deactivation of the light-emitting material of the light-emitting layer may occur due to generation of Auger electrons, which is a deactivation process, or the like.

In the blue light-emitting element 6B according to the present embodiment, the injection efficiency of holes relative to the injection efficiency of electrons into the blue light-emitting layer 14B is high compared with that in the blue light-emitting element 6BA according to the comparative embodiment. As a result, the blue light-emitting element 6B reduces the electron excess in the blue light-emitting layer 14B and further improves the luminous efficiency.

In particular, the blue light-emitting layer 14B includes the insulating layer 24 that includes the insulating material 28 without including the blue quantum dot 26B or the ligand 30 on the cathode 18 side of the blue quantum dot layer 22B. Therefore, the blue light-emitting element 6B can more simply and reliably form a structure in which the gap 14DA is smaller than the gap 14DC.

Further, at least one of the blue quantum dot 26B or the ligand 30 positioned in the end face portion 14BA on the end face 14EA side of the blue light-emitting element 6B is in contact with the hole transport layer 12B. On the other hand, at least one of the blue quantum dot 26B or the ligand 30 positioned in the end face portion 14BC on the end face 14EC side of the blue light-emitting element 6B is separated from the electron transport layer 16 by the insulating layer 24. Therefore, the blue light-emitting element 6B further reduces the injection of electrons from the electron transport layer 16 into the blue quantum dot 26B via the ligand 30.

In the present embodiment, the carrier mobility of the insulating material 28 is less than 10⁻⁶ cm²/V·sec, for example. For example, the carrier mobility of an organic material typically used for the ligand 30 is about 10⁻⁶ cm²/V·sec. Therefore, according to the configuration described above, the insulating material 28 achieves a lower mobility than the ligand 30, and efficiently reduces the generation of the reactive current WC in the blue light-emitting layer 14B.

In the present embodiment, the insulating material 28 has a light transmittance of 80% or greater in the visible light region, for example. With the configuration described above, the insulating material 28 is less likely to block light from the blue quantum dot 26B. Accordingly, according to the configuration described above, the insulating material 28 suppresses a reduction in light extraction efficiency from the blue light-emitting element 6B.

In the present embodiment, a thickness 24D of the insulating layer 24 is from 2 nm to 5 nm, for example. When the thickness 24D is 2 nm or greater, the insulating layer 24 can be more easily and reliably formed as a continuous film. When the thickness 24D is 5 nm or less, electrons are injected from the electron transport layer 16 into the blue quantum dot layer 22B by the tunneling of the electrons in the insulating layer 24. Therefore, with the thickness 24D being 5 nm or less, the insulating layer 24 suppresses a rise in the overall resistance value of the blue light-emitting element 6B.

Each of the red light-emitting element 6R and the green light-emitting element 6G has the same configuration as that of the blue light-emitting element 6B except for the type of quantum dot included in the light-emitting layer. Accordingly, each of the red light-emitting element 6R and the green light-emitting element 6G has the same effect as that of the blue light-emitting element 6B.

The display device 2 including, on a subpixel-by-subpixel basis, the red light-emitting element 6R, the green light-emitting element 6G, and the blue light-emitting element 6B with further improved luminous efficiency further reduces power consumption. Furthermore, in the display device 2, to obtain the same light emission intensity from each light-emitting element, the voltage applied to each light-emitting element can be reduced, and the lifetime of each light-emitting element is further improved.

### Method for Manufacturing Display Device

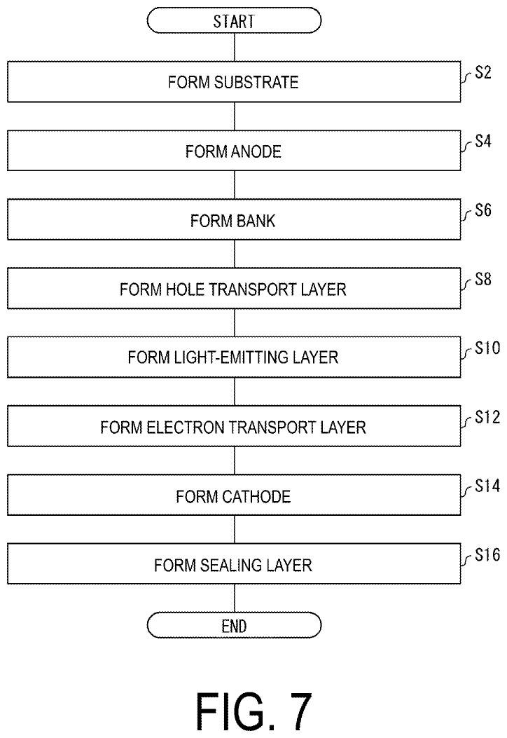

A method for manufacturing the display device 2 according to the present embodiment will now be described with reference to FIG. 7. FIG. 7 is a flowchart for describing the method for manufacturing the display device 2 according to the present embodiment.

In the method for manufacturing the display device 2 according to the present embodiment, first, the substrate 4 is formed (step S2). The substrate 4 may be formed by, for example, forming, on a rigid glass substrate, a film base material and TFTs on the film base material, and then peeling the glass substrate from the film base material. The peeling of the glass substrate described above may be executed after formation of the light-emitting element layer 6 and the sealing layer 8 described below. Alternatively, the substrate 4 may be formed by, for example, forming the TFTs directly on a rigid glass substrate.

Next, the anode 10 is formed on the substrate 4 (step S4). The anode 10 may be formed by, for example, forming a thin film of a metal material by sputtering or the like, and then patterning the thin film by dry etching or wet etching using a photoresist. Thus, the anode 10R, the anode 10G, and the anode 10B formed into island shapes on a subpixel-by-subpixel basis on the substrate 4 are obtained.

Next, the bank 20 is formed (step S6). In step S6, the bank 20 is formed by photolithography of a positive-working photosensitive resin. Specifically, for example, a positive-working photosensitive resin serving as a material of the bank 20 is applied to the upper faces of the substrate 4 and the anode 10. Next, a photomask having a light-transmitting portion at a position corresponding to each subpixel is placed above the applied photosensitive resin, and the photosensitive resin is irradiated with ultraviolet light or the like through the photomask. Then, the photosensitive resin irradiated with the ultraviolet light is cleaned with an appropriate developing solution. Thus, the bank 20 is formed between the positions corresponding to the subpixels on the substrate 4.

In general, as a distance between the photomask and an exposure target increases, an exposure area and an exposure intensity of the photomask in plan view tend to decrease. For this reason, when formed by photolithography using a positive-working photosensitive resin, the bank 20 is formed gradually smaller upwardly from the substrate 4 side. Accordingly, in step S6, the bank 20 is formed by applying, exposing, and developing the positive-working photosensitive resin, making it possible to form the bank 20 having the side surface 20S that is a forwardly tapered face.

Next, the hole transport layer 12 is formed (step S8). The hole transport layer 12 may be formed by, for example, applying a material having hole transport properties and then patterning the thin film by dry etching or wet etching using a photoresist. As a result, the hole transport layer 12R, the hole transport layer 12G, and the hole transport layer 12B formed into island shapes on the anode 10 on a subpixel-by-subpixel basis are obtained.

### Method for Forming Light-Emitting Layer

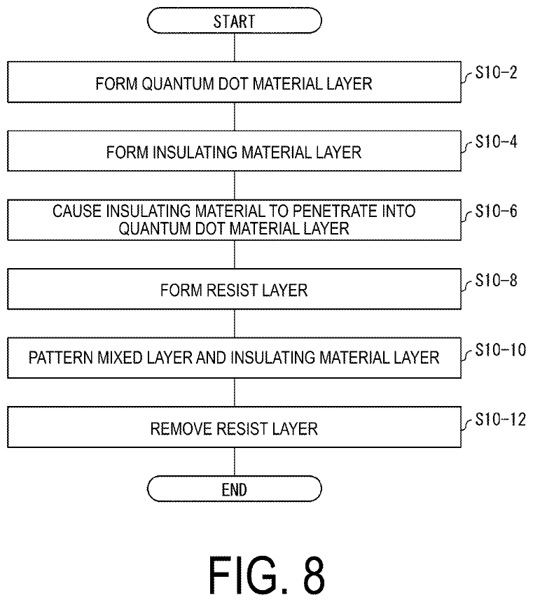

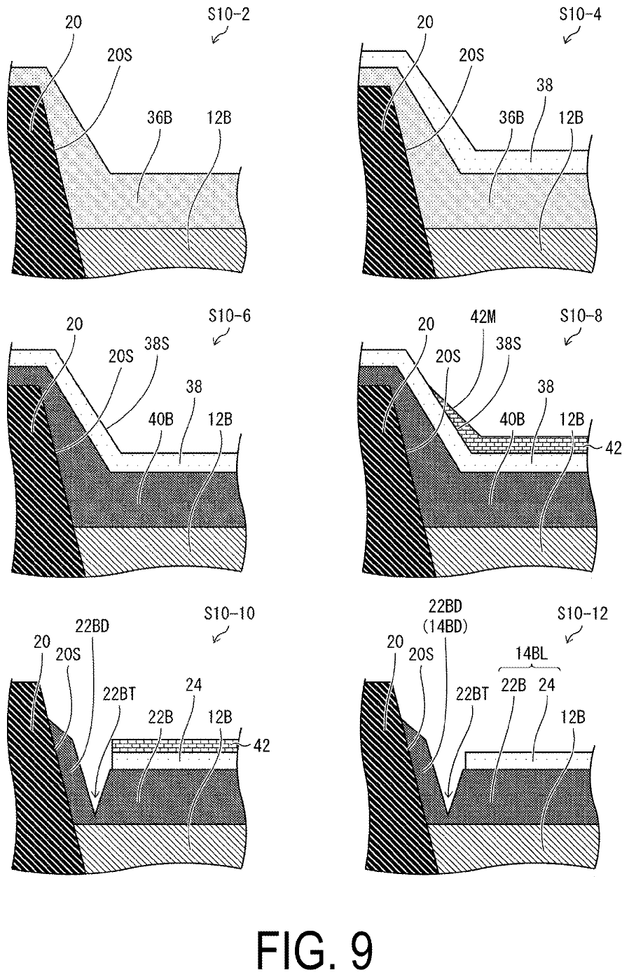

Next, the light-emitting layer 14 is formed (step S10). A method for forming the light-emitting layer 14 will now be further described in more detail with reference to FIG. 8 and FIG. 9. Hereinafter, the method for forming the light-emitting layer 14 in each embodiment including the present embodiment will be described using the method for forming the blue light-emitting layer 14B as a representative. FIG. 8 is a flowchart for describing the method for forming the light-emitting layer 14 according to the present embodiment. FIG. 9 illustrates process cross-sectional views of the vicinity of the side surface 20S of the bank 20 positioned in the blue subpixel SPB in the process of forming the light-emitting layer 14 according to the present embodiment. Note that each process cross-sectional view illustrated in the present specification including FIG. 9 illustrates a cross section at a position corresponding to the cross section illustrated in FIG. 4, unless otherwise specified.

First, a material including the blue quantum dots 26B is formed into a film on the entire surface of an upper layer overlying the hole transport layer 12B and the bank 20 to form a blue quantum dot material layer 36B (step S10-2). In other words, in step S10-2, the blue quantum dot material layer 36B is formed not only for the blue subpixel SPB but also for the red subpixel SPR and the green subpixel SPG. Therefore, the blue quantum dot material layer 36B is also formed on the side surface 20S of the bank 20.

The blue quantum dot material layer 36B may be formed by applying a solution including the blue quantum dots 26B using an application method using a coater or the like. The solution may include the blue quantum dots 26B, a solvent in which the blue quantum dots 26B are dispersed, and the ligands 30 for improving the dispersibility of the blue quantum dots 26B in the solvent.

Next, a material including the insulating material 28 is formed into a film on the blue quantum dot material layer 36B, thereby forming an insulating material layer 38 (step S10-4). The insulating material layer 38 may be formed by applying a solution including the insulating material 28 using an application method using a coater, for example. Note that the insulating material layer 38 is formed on an entire upper face of the blue quantum dot material layer 36B. Therefore, on an upper face of the insulating material layer 38, an inclined face 38S reflecting the inclination of the side surface 20S of the bank 20 is formed around the blue subpixel SPB.

The insulating material 28 may include an amorphous material, for example. In this case, the insulating material layer 38 can be formed by diluting the insulating material 28 with an appropriate solvent and applying the diluted solution. Further, with the insulating material 28 including an amorphous material, it is possible to form a stable layer including the insulating material 28 by applying a heat treatment or the like to the insulating material layer 38 and curing the amorphous material included in the insulating material 28 in a post-process.

For example, the insulating material 28 may include a glass-based material including spin-on-glass (SOG). In this case, the solution including the insulating material 28 may include, as a solvent, an ether-based solvent including diethyl ether, dioxolane, dioxane, tetrahydrofuran, or the like.

Further, for example, the insulating material 28 may include a tetrafluoroethylene-based material including polytetrafluoroethylene (PTFE; CYTOP). In this case, the solution including the insulating material 28 may include, as a solvent, a perfluoro-based solvent including a fluorous alcohol, a fluorous ether, a fluorous hexane, or the like.

Alternatively, for example, the insulating material 28 may include a silicone-based material including dimethyl silicone. In this case, the solution including the insulating material 28 may include, as a solvent, a hydrocarbon-based solvent including toluene, xylene, or the like.

According to the configuration described above, the insulating material 28 can be dissolved in an appropriate solvent, making it possible to more easily form the insulating material layer 38. Note that the insulating material 28 may include a plurality of materials among the materials described above.

Next, the insulating material layer 38 positioned on the blue quantum dot material layer 36B is maintained, causing a portion of the insulating material 28 included in the insulating material layer 38 to penetrate into the blue quantum dot material layer 36B (step S10-6). Step S10-6 may be executed by allowing the substrate 4 to stand for about 30 minutes following step S10-4. As a result, a mixed layer 40B including the blue quantum dots 26B and the insulating material 28 is formed immediately below the insulating material layer 38.

Next, the resist layer 42 is formed in an upper layer overlying the insulating material layer 38 (step S10-8). Here, the resist layer 42 is formed into an island shape at a position overlapping, in plan view of the substrate 4, the blue subpixel SPB in which the blue light-emitting layer 14B is formed. The resist layer 42 may be formed by, for example, applying a material of the resist layer including a photosensitive resin and patterning the material by photolithography.

When the resist layer 42 is formed by applying a material and patterning the material as described above, the material of the resist layer 42 is also formed into a film on the inclined face 38S of the insulating material layer 38 that is formed along the side surface 20S of the bank 20. Further, with the material of the resist layer 42 thus formed being patterned, the material of the resist layer 42 also remains at a position adjacent to the inclined face 38S.

Here, a portion of the resist layer 42 that is formed at a position adjacent to the inclined face 38S creeps up the inclined face 38S due to the meniscus effect. Therefore, in step S10-8, an outer edge portion 42M of the resist layer 42 is thinly formed on the inclined face 38S as well. Accordingly, after execution of step S10-8, the insulating material layer 38 and the mixed layer 40B are covered with the outer edge portion 42M of the resist layer 42 at a position overlapping the side surface 20S of the bank 20 in plan view of the substrate 4, the outer edge portion 42M being relatively thin.

Next, the insulating material layer 38 and the mixed layer 40B are etched by an appropriate etching method to pattern the insulating material layer 38 and the mixed layer 40B (step S10-10). The resist layer 42 includes a material resistant to the etching of the insulating material layer 38 and the mixed layer 40B. Therefore, in step S10-10, only the insulating material layer 38 and the mixed layer 40B in a lower layer thereof that are exposed from the resist layer 42 are etched in plan view of the substrate 4. As a result, the mixed layer 40B having an island shape and the insulating material layer 38 are formed for each blue subpixel SPB, and become the blue quantum dot layer 22B and the insulating layer 24, respectively.

The insulating material layer 38 and the mixed layer 40B are etched by dry etching or wet etching. For example, the insulating material layer 38 and the mixed layer 40B are etched by removing the insulating material layer 38 and the mixed layer 40B exposed from the resist layer 42 by an appropriate etching material.

For example, when the insulating material 28 includes SOG, the insulating material layer 38 can be removed by an etching material including hydrofluoric acid, buffered hydrofluoric acid, or the like. Further, when the insulating material 28 includes PTFE or dimethyl silicone, the insulating material layer 38 can be removed by ashing using O₂ or O₂ plasma, reactive ion etching (RIE), or the like. With the configuration described above, the insulating material layer 38 and the mixed layer 40B can be etched more reliably.

When step S10-8 is completed, the resist layer 42 is thinly formed as the outer edge portion 42M also on the inclined face 38S of the insulating material layer 38 positioned around the blue subpixel SPB. Therefore, in plan view of the substrate 4, the insulating material layer 38 and the mixed layer 40B at the position overlapping the outer edge portion 42M are etched more weakly than the etching of the insulating material layer 38 and the mixed layer 40B exposed from the resist layer 42.

Accordingly, by execution of step S10-10, a portion of the mixed layer 40B remains on the side surface 20S of the bank 20 without being etched. However, in plan view of the substrate 4, by the etching of the insulating material layer 38 and the mixed layer 40B at a position overlapping the outer edge portion 42M, the insulating material layer 38 at that position is removed, and the mixed layer 40B is exposed to the etching material.

In particular, the etching in step S10-10 is executed by dry etching or wet etching. In this case, the blue quantum dots 26B remaining on the side surface 20S of the bank 20 and included in the mixed layer 40B exposed to the etching material are deteriorated and deactivated by oxidation or the like. Therefore, when step S10-10 is completed, the deactivation layer 22BD that is thinner than the blue quantum dot layer 22B and includes the deactivated blue quantum dots 26B is formed on the side surface 20S of the bank 20. Note that, upon completion of step S10-10, the thin film portion 22BT thinner than the surrounding area may be formed at a boundary between the blue quantum dot layer 22B and the deactivation layer 22BD.

Next, the resist layer 42 is removed from above the insulating material layer 38 by cleaning the resist layer 42 that remains with an appropriate remover (step S10-12). Thus, the main light-emitting portion 14BL, including the blue quantum dot layer 22B and the insulating layer 24, and the outer edge portion 14BD, including the deactivation layer 22BD, are obtained.

With the above, the process of forming the blue light-emitting layer 14B is completed. Note that, in step S10-6 and thereafter, the solvent in the insulating material layer 38 may be volatilized and the amorphous material included in the insulating material 28 may be cured by heat treatment of the insulating material layer 38 or the like. In this case, a compound derived from the solvent included in the insulating material layer 38 may remain as a second compound in the blue light-emitting layer 14B.

The red light-emitting layer 14R and the green light-emitting layer 14G may be formed by partially changing the process of forming the blue light-emitting layer 14B described above, and executing the changed process. For example, in the process of forming the red light-emitting layer 14R and the green light-emitting layer 14G, the blue quantum dots 26B included in the blue quantum dot material layer 36B in the process of forming the blue light-emitting layer 14B are changed to red quantum dots and green quantum dots, respectively. Further, in the process of forming the red light-emitting layer 14R and the green light-emitting layer 14G, the position where the resist layer 42 is formed in step S10-8 described above is changed to positions overlapping the red subpixel SPR and the green subpixel SPG, respectively, in plan view of the substrate 4. With the above, the process of forming the light-emitting layer 14 according to the present embodiment can be executed.

### Method for Forming Remaining Portion

Following the step of forming the light-emitting layer 14, the second electron transport layer 16 is formed (step S12). The electron transport layer 16 may be formed in common to the subpixels by applying a material having electron transport properties, for example. Next, the cathode 18 is formed on the electron transport layer 16 (step S14). The cathode 18 may be formed by, for example, forming a thin film of a metal material in common to the subpixels by sputtering. With the above, formation of the light-emitting element layer 6 is completed.

Next, the sealing layer 8 is formed (step S16). In a case in which the sealing layer 8 includes an organic sealing film, the organic sealing film may be formed by applying an organic sealing material. Further, in a case in which the sealing layer 8 includes an inorganic sealing film, the inorganic sealing film may be formed by CVD or the like. Thus, the sealing layer 8 that seals the light-emitting element layer 6 is formed, and the manufacture of the display device 2 is completed.

### Effects of Manufacturing Method

The method for forming the blue light-emitting element 6B according to the present embodiment includes, for example, a penetration process of forming the insulating material layer 38 in an upper layer overlying the blue quantum dot material layer 36B and causing a portion of the insulating material 28 in the insulating material layer 38 to penetrate into the blue quantum dot material layer 36B. In the penetration process, the insulating material 28 penetrated into the blue quantum dot material layer 36B is a portion of the insulating material 28 in the insulating material layer 38, and thus the insulating material layer 38 remains in an upper layer overlying the blue quantum dot material layer 36B. Accordingly, by the method for forming the blue light-emitting element 6B described above, the blue light-emitting element 6B including the layering of the blue quantum dot layer 22B and the insulating layer 24 can be obtained. Therefore, by the formation method described above, the blue light-emitting element 6B in which the gap 14DA is smaller than the gap 14DC can be easily formed.

Further, due to the penetration process described above, the method for manufacturing the display device 2 according to the present embodiment does not require a process of separately applying a material obtained by mixing the blue quantum dots 26B and the insulating material 28. This makes it possible to select a more appropriate solvent for dispersing the blue quantum dots 26B as the material of the blue quantum dot material layer 36B.

Furthermore, by the penetration process described above, it is possible to easily form the mixed layer 40B in which the density of the insulating material 28 gradually increases from the anode 10 side to the cathode 18 side. The blue light-emitting element 6B including the blue quantum dot layer 22B manufactured by the manufacturing method described above can more efficiently improve the efficiency of hole injection from the anode 10 side relative to the efficiency of electron injection from the cathode 18 side.

For example, assume for the moment that the blue light-emitting layer 14B is divided into two portions, a portion on the anode 10 side and a portion on the cathode 18 side, from a center position of the blue light-emitting element 6B in a layering direction. By the method for forming the blue light-emitting layer 14B including the penetration process described above, the blue light-emitting layer 14B can be formed with an average density of the insulating material 28 being higher in the portion on the cathode 18 side than in the portion on the anode 10 side, from the above-described center position of the blue light-emitting layer 14B.

Further, assume for the moment that the blue light-emitting layer 14B is equally divided into three portions, a first portion, a second portion positioned closer to the cathode 18 than the first portion, and a third portion positioned closer to the cathode 18 than the second portion, in the layering direction of the blue light-emitting element 6B from the anode 10 side. In particular, the first portion includes the end face 14EA and the third portion includes the end face 14EC. By the method for forming the blue light-emitting layer 14B including the penetration process described above, the blue light-emitting layer 14B can be formed with an average density of the insulating material 28 increasing in the order of the first portion, the second portion, and the third portion.

Alternatively, by the method for forming the blue light-emitting layer 14B including the penetration process described above, the blue light-emitting layer 14B can be formed with the average density of the insulating material 28 gradually increasing from the anode 10 side to the cathode 18 side.

For example, assume for the moment a cross section obtained by cutting the blue light-emitting layer 14B at an arbitrary cross section in the normal direction of any surface of the blue light-emitting layer 14B. In this case, the quantity of the insulating material 28 per unit surface area on the cut surface is calculated. Thus, a magnitude relationship of the average density of the insulating material 28 included in the blue light-emitting layer 14B may be measured by comparing the quantity of the insulating material 28 per unit surface area.

Further, in a case in which the measurement described above is difficult, a time-of-flight secondary ion mass spectrometry (TOF-SIMS) technique may be used as a technique for directly observing molecules of the insulating material 28 and a concentration of the molecules of the insulating material 28. The TOF-SIMS technique is a method of sputtering a minute region, on the order of micrometers, on one side of a measurement target, and determining a mass of the substance liberated by a time of flight of the substance. A type of the substance can be identified by comparing the mass detected by the technique with a database. By using the TOF-SIMS technique, it is possible to directly quantify the type and the mass of the substance from the order of atoms to the order of macromolecules.

In addition to the method described above, the molecules of the insulating material 28 and the concentration of the molecules of the insulating material 28 can be observed by using a gas chromatography mass spectrometry (GCMS) technique. The GCMS technique is a method for qualitatively and quantitatively analyzing an object subject to analysis by gas chromatography and mass spectrometry. Alternatively, in a case in which measurement by the method described above is difficult, an energy dispersive X-ray spectroscopy (EDX) technique may be used.

Comparison of measurement results in a method among the methods described above that does not specify the comparison method of the measurement results may be implemented by a method such as follows. For example, on a cut face obtained by cutting the blue light-emitting layer 14B at any cross section, a detection amount of a specific element included in the composition of the insulating material 28 in a certain measurement range is measured. Further, for the comparison, the measurement described above is implemented as appropriate on any line segment parallel to the normal line of the surface of the blue light-emitting layer 14B on the cut face described above. Accordingly, the magnitude relationship of the average density of the insulating material 28 included in the blue light-emitting layer 14B may be determined by comparing the magnitude relationship of the average detection amount on the line segment within a range of comparison as appropriate. Note that, although the measurement methods described above are preferred, when measurement is difficult by the measurement methods described above, the measurement may be performed by another method.

The insulating material layer 38 formed in step S10-4 according to the present embodiment may include the insulating material 28, including a tetrafluoroethylene-based material, and a perfluoro-based solvent. In this case, the blue quantum dot material layer 36B formed in step S10-2 according to the present embodiment may include the ligands 30 soluble in the perfluoro-based solvent. In this case, the mixing of the blue quantum dot material layer 36B, which is a colloidal solution including the blue quantum dots 26B, and the insulating material layer 38 including the perfluoro-based solvent is promoted. Therefore, with the configuration described above, it is possible to more effectively execute the penetration process in step S10-6 according to the present embodiment.

In step S10-8 according to the present embodiment, the insulating material layer 38 is formed in an upper layer overlying the mixed layer 40B. The insulating material layer 38 can therefore protect the mixed layer 40B from the developing solution used for patterning the resist layer 42, thereby reducing deterioration of the blue quantum dots 26B.

Further, in step S10-10 according to the present embodiment, the insulating material layer 38 and the mixed layer 40B are patterned by dry etching or wet etching. Therefore, by step S10-10, at the position covered with the outer edge portion 42M of the resist layer 42, the deactivation layer 22BD, including the deactivated blue quantum dots 26B, and the outer edge portion 14BD including the deactivation layer 22BD are formed.

Therefore, the luminous efficiency of the outer edge portion 14BD, which is included in the blue light-emitting element 6B formed by the formation method described above, is extremely low because the included blue quantum dots 26B are deactivated. Accordingly, by forming the blue light-emitting element 6B by the formation method described above, abnormal light emission by the outer edge portion 14BD can be reduced.

Therefore, the blue light-emitting element 6B can make the carriers injected into the blue light-emitting layer 14B efficiently contribute to light emission of the main light-emitting portion 14BL, thereby improving the luminous efficiency of the main light-emitting portion 14BL. Further, the blue light-emitting element 6B includes, at the outer edge of the main light-emitting portion 14BL, the outer edge portion 14BD having a low luminous efficiency. Thus, the blue light-emitting element 6B can reduce the light emission intensity at or near the boundary with the other light-emitting elements. As a result, the display device 2 including the blue light-emitting element 6B can reduce color mixing between subpixels, improving the display quality.

Furthermore, in step S10-12 according to the present embodiment, the insulating layer 24 is formed in an upper layer overlying the blue quantum dot layer 22B. The insulating layer 24 can therefore protect the blue quantum dot layer 22B from the remover used for removing the resist layer 42, thereby reducing deterioration of the blue quantum dot layer 26B.

Note that, after completion of step S10-10 according to the present embodiment, a portion of the blue quantum dot layer 22B that is patterned may creep up an upper face of the deactivation layer 22BD due to the meniscus effect. In this case as well, with the deactivation layer 22BD including the deactivated blue quantum dots 26B formed in the outer edge portion 14BD, the luminous efficiency of the outer edge portion 14BD is still sufficiently lower than that of the main light-emitting portion 14BL.

The methods for forming the red light-emitting element 6R and the green light-emitting element 6G according to the present embodiment can be executed by simply changing the material of the quantum dots and the formation position of the light-emitting layer 14 in the method for forming the blue light-emitting element 6B. Accordingly, the methods for forming the red light-emitting element 6R and the green light-emitting element 6G according to the present embodiment also achieve the same effects as those of the method for forming the blue light-emitting element 6B.

### Second Embodiment

### Quantum Dot Layer Not Including Insulating Material

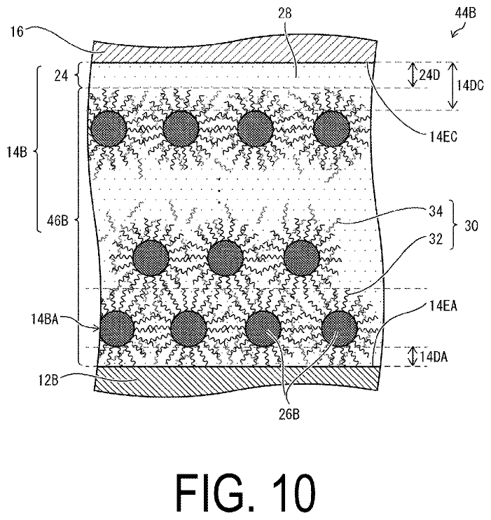

FIG. 10 is an enlarged schematic view illustrating a partial region of a schematic cross section of the display device 2 according to the present embodiment, and is an enlarged view of a position corresponding to the enlarged schematic view of the display device 2 illustrated in FIG. 1. As compared with the display device 2 according to the previous embodiment, the display device 2 according to the present embodiment includes a red light-emitting element 44R, a green light-emitting element 44G, and a blue light-emitting element 44B instead of the red light-emitting element 6R, the green light-emitting element 6G, and the blue light-emitting element 6B, respectively. Otherwise, the display device 2 according to the present embodiment has the same configuration as that of the display device 2 according to the previous embodiment.

In the blue light-emitting element 44B according to the present embodiment, as compared with the blue light-emitting element 6B according to the previous embodiment, the blue light-emitting layer 14B further includes a blue quantum dot layer 46B including the blue quantum dots 26B and the ligands 30 on the anode 10 side. In particular, among the materials included in the blue quantum dot layer 22B, the blue quantum dot layer 46B does not include the insulating material 28.

Note that the blue quantum dot layer 46B forms the end face 14EA of the blue light-emitting layer 14B on the anode 10 side, and is in contact with the hole transport layer 12B. Therefore, the end face portion 14BA in the present embodiment refers to an area from the end face 14EA to a portion where, of the blue quantum dots 26B included in the blue quantum dot layer 46B, 20 blue quantum dots 26B closest to the end face 14EA are positioned.

Otherwise, the blue light-emitting element 44B according to the present embodiment has the same configuration as that of the blue light-emitting element 6B according to the previous embodiment. For example, in the present embodiment, the blue quantum dot layer 46B does not include the insulating material 28 between the blue quantum dots 26B. On the other hand, the blue light-emitting element 44B according to the present embodiment includes the insulating layer 24 including the insulating material 28 on the cathode 18 side of the blue quantum dot layer 46B, similarly to the blue light-emitting element 6B according to the previous embodiment. Further, in the present embodiment, the gap 14DA is smaller than the gap 14DC.

As described above, the blue light-emitting element 44B reduces the occurrence of a reactive current and the occurrence of electron excess in the blue light-emitting layer 14B for the same reasons as those described in the previous embodiment. Therefore, the blue light-emitting element 44B improves the luminous efficiency and extends the lifetime.

Further, the blue light-emitting element 44B includes the blue quantum dot layer 46B that does not include the insulating material 28 on the anode 10 side of the blue light-emitting layer 14B. In particular, the blue quantum dot layer 46B includes only the blue quantum dots 26B and the ligands 30 among the materials included in the blue quantum dot layer 22B. As a result, the blue light-emitting element 44B can further improve the efficiency of hole injection from the anode 10 side via the ligands 30 and the like while realizing a reduction in the reactive current and a reduction in electron excess.

Furthermore, as compared with the blue light-emitting element 44B, the red light-emitting element 44R and the green light-emitting element 44G according to the present embodiment have the same configuration except for the luminescent color of the quantum dots included in the light-emitting layer 14. Accordingly, each of the red light-emitting element 44R and the green light-emitting element 44G has the same effect as that of the blue light-emitting element 44B.

### Mixed Layer Formation Process

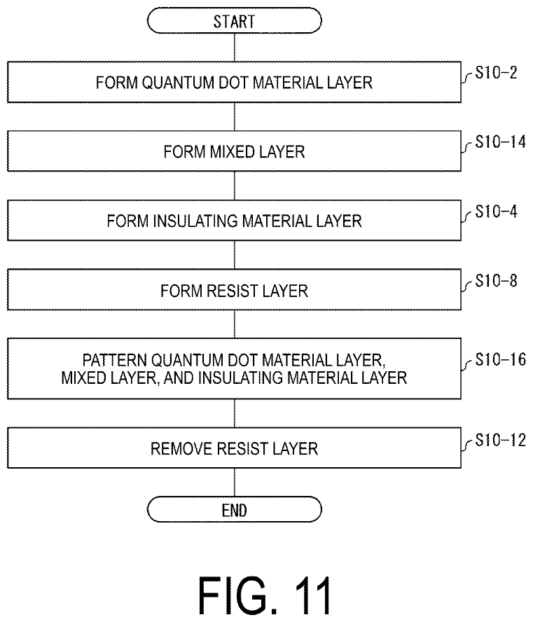

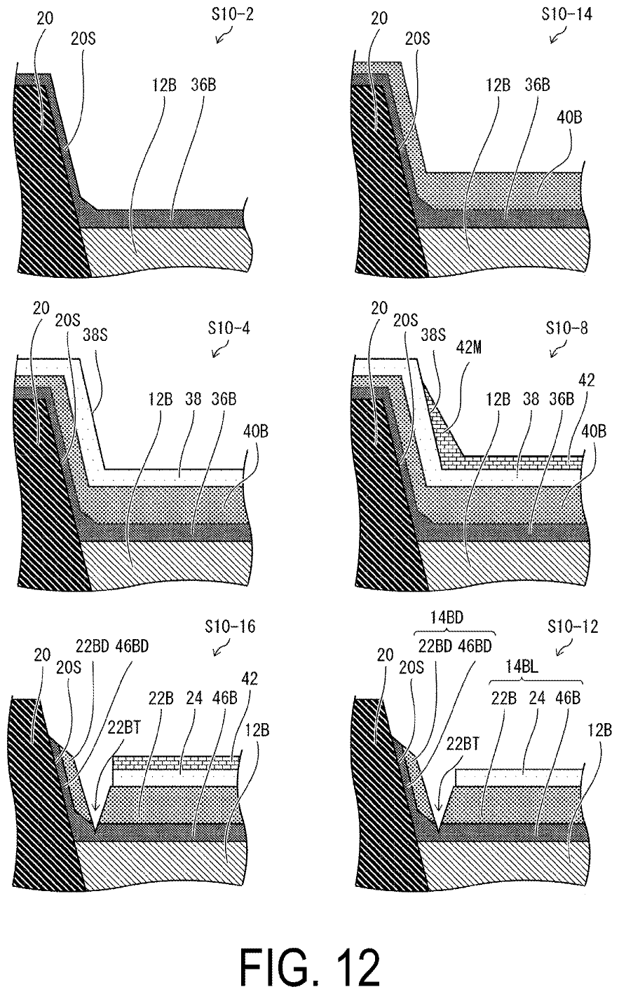

The display device 2 according to the present embodiment can be manufactured by the same method as the method for manufacturing the display device 2 according to the previous embodiment by changing only the formation process of the light-emitting layer. The method for forming the light-emitting layer 14 according to the present embodiment will now be described in more detail with reference to FIG. 11 and FIG. 12. FIG. 11 is a flowchart for describing the method for forming the light-emitting layer 14 according to the present embodiment. FIG. 12 illustrates process cross-sectional views of the vicinity of the side surface 20S of the bank 20 positioned in the blue subpixel SPB in the process of forming the light-emitting layer 14 according to the present embodiment.

In the process of forming the blue light-emitting layer 14B according to the present embodiment, first, the blue quantum dot material layer 36B is formed by the same technique as in step S10-2 according to the previous embodiment. Here, in step S10-2 according to the present embodiment, in consideration of the film thickness of the blue quantum dot layer 46B, the blue quantum dot material layer 36B may be formed thinner compared with step S10-2 according to the previous embodiment.

Next, the mixed layer 40B is formed on the blue quantum dot material layer 36B by applying a material obtained by mixing the blue quantum dots 26B and the insulating material 28 (step S10-14). The mixed layer 40B may further include the ligands 30 and may include a solvent in which the insulating material 28 is soluble.

Note that the mixed layer 40B according to the present embodiment may include the same material as that of the mixed layer 40B according to the previous embodiment. However, with the mixed layer 40B according to the present embodiment being formed from a solution obtained by mixing the blue quantum dots 26B and the insulating material 28, the density of the insulating material 28 is more uniform than that of the mixed layer 40B according to the previous embodiment.

Next, the insulating material layer 38 is formed on the mixed layer 40B by the same technique as that in step S10-4 according to the previous embodiment. In the present embodiment as well, on the upper face of the insulating material layer 38, the inclined face 38S reflecting the inclination of the side surface 20S of the bank 20 is formed around the blue subpixel SPB.

Next, the resist layer 42 is formed in an upper layer overlying the insulating material layer 38 for each blue subpixel SPB by the same technique as that in step S10-8 according to the previous embodiment. In the present embodiment as well, a portion of the resist layer 42 formed at a position adjacent to the inclined face 38S creeps up the inclined face 38S due to the meniscus effect. Accordingly, after execution of step S10-8, the insulating material layer 38 and the mixed layer 40B are covered with the outer edge portion 42M of the resist layer 42 at a position overlapping the side surface 20S of the bank 20 in plan view of the substrate 4, the outer edge portion 42M being relatively thin.

Next, the blue quantum dot material layer 36B, the insulating material layer 38, and the mixed layer 40B are etched by an appropriate etching method to pattern the blue quantum dot material layer 36B, the insulating material layer 38, and the mixed layer 40B (step S10-16). The blue quantum dot material layer 36B can be etched by an etching material that can etch the insulating material layer 38 and the mixed layer 40B. Accordingly, step S10-16 can be executed by the same method as that in step S10-10 according to the previous embodiment, except that the blue quantum dot material layer 36B is further patterned. As a result, the blue quantum dot material layer 36B, the mixed layer 40B, and the insulating material layer 38 having island shapes are formed for each blue subpixel SPB, and become the blue quantum dot layer 46B, the blue quantum dot layer 22B, and the insulating layer 24, respectively.

In the present embodiment as well, when step S10-8 is completed, the resist layer 42 is also thinly formed as the outer edge portion 42M on the inclined face 38S of the insulating material layer 38 positioned around the blue subpixel SPB. Thus, by execution of step S10-16, a portion of each of the blue quantum dot material layer 36B and the mixed layer 40B remains on the side surface 20S of the bank 20 without being etched. However, the blue quantum dot material layer 36B and the mixed layer 40B at this position are exposed to the etching material under the same circumstances as those described in the previous embodiment.

In particular, the etching in step S10-16 is executed by dry etching or wet etching. In this case, the blue quantum dots 26B remaining on the side surface 20S of the bank 20 and included in the blue quantum dot material layer 36B and the mixed layer 40B exposed to the etching material are deteriorated and deactivated by oxidation or the like. Therefore, when step S10-16 is completed, a deactivation layer 46BD and the deactivation layer 22BD are formed on the side surface 20S of the bank 20 in this order from the bank 20 side. Note that the deactivation layer 46BD is formed by deactivation of the blue quantum dots 26B of the blue quantum dot material layer 36B, and the deactivation layer 22BD is formed by deactivation of the blue quantum dots 26B of the mixed layer 40B.

Next, the resist layer 42 is removed from above the insulating material layer 38 by the same technique as that in step S10-12 according to the previous embodiment. Thus, the main light-emitting portion 14BL, including the blue quantum dot layer 46B, the blue quantum dot layer 22B, and the insulating layer 24, and the outer edge portion 14BD, including the deactivation layer 46BD and the deactivation layer 22BD, are obtained.

The red light-emitting layer 14R and the green light-emitting layer 14G may be formed by partially changing the process of forming the blue light-emitting layer 14B described above in accordance with the method described in the previous embodiment, and executing the changed process. With the above, the process of forming the light-emitting layer 14 according to the present embodiment can be executed.

In the formation method of the blue light-emitting element 6B according to the present embodiment, in step S10-14, the mixed layer 40B is formed from a solution obtained by mixing the blue quantum dots 26B and the insulating material 28. Therefore, according to the formation method, it is possible to form the blue quantum dot layer 22B in which the density of the insulating material 28 is more uniform, and form the blue light-emitting layer 14B in which the reactive current is reduced by enhanced stability.

Further, in the formation method described above, the blue quantum dot material layer 36B that does not include the insulating material 28 is formed in step S10-2. As a result, in the formation method, the blue quantum dot layer 46B that does not include the insulating material 28 can be more reliably formed on the anode 10 side of the blue light-emitting layer 14B. In addition, the formation method does not include a process of causing the insulating material 28 to penetrate into the blue quantum dot material layer 36B. As a result, in the present embodiment, the penetration process in the previous embodiment can be omitted, thereby further simplifying the formation method described above.

The mixed layer 40B formed in step S10-14 according to the present embodiment may include the insulating material 28 including a tetrafluoroethylene-based material, a perfluoro-based solvent, and the ligands 30 soluble in the perfluoro-based solvent. In this case, the colloidal mixture of the blue quantum dots 26B, the insulating material 28 soluble in a perfluoro-based solvent, and the ligands 30 similarly soluble in a perfluoro-based solvent is promoted. With the configuration described above, in step S10-14 according to the present embodiment, the mixing of the solution used for forming the mixed layer 40B is further promoted, making it possible to form the mixed layer 40B that is more uniform.

### Third Embodiment

Quantum Dot Layer with Reduced Excess Ligands

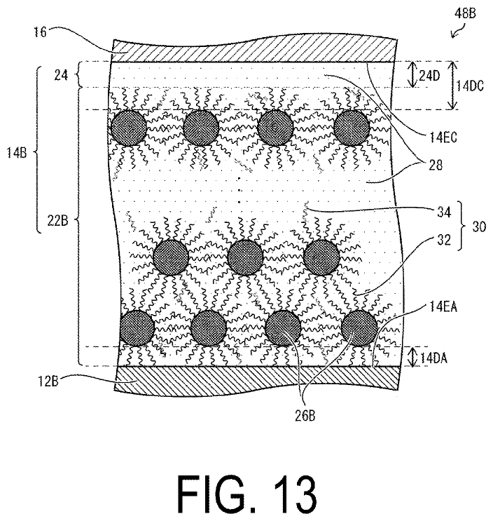

FIG. 13 is an enlarged schematic view illustrating a partial region of a schematic cross section of the display device 2 according to the present embodiment, and is an enlarged view of a position corresponding to the enlarged schematic view of the display device 2 illustrated in FIG. 1. As compared with the display device 2 according to the first embodiment, the display device 2 according to the present embodiment includes a red light-emitting element 48R, a green light-emitting element 48G, and a blue light-emitting element 48B instead of the red light-emitting element 6R, the green light-emitting element 6G, and the blue light-emitting element 6B, respectively. Otherwise, the display device 2 according to the present embodiment has the same configuration as that of the display device 2 according to the first embodiment.

The blue light-emitting element 48B according to the present embodiment, as compared with the blue light-emitting element 6B according to the first embodiment, has a low concentration of the excess ligands 34 among the ligands 30 included in the blue quantum dot layer 22B of the blue light-emitting layer 14B. Specifically, the number of the excess ligands 34 included in the blue quantum dot layer 22B according to the present embodiment is few compared with the number of the excess ligands 34 included in the blue quantum dot layer 22B according to the first embodiment. For example, in the present embodiment, a ratio of the excess ligands 34 included in the blue quantum dot layer 22B to the binding ligands 32 included in the blue quantum dot layer 22B is low. Otherwise, the blue light-emitting element 48B according to the present embodiment has the same configuration as that of the blue light-emitting element 6B according to the first embodiment.

The blue light-emitting element 48B reduces the occurrence of a reactive current and the occurrence of electron excess in the blue light-emitting layer 14B for the same reasons as those described in the first embodiment. Therefore, the blue light-emitting element 48B improves the luminous efficiency and extends the lifetime.

Further, the concentration of the excess ligands 34 included in the blue quantum dot layer 22B according to the present embodiment is lower than the concentration of the excess ligands 34 included in the blue quantum dot layer 22B according to each of the embodiments described above. The excess ligands 34 have a long average value of a gap to the closest blue quantum dot 26B compared with that of the binding ligands 32. For this reason, as compared with the binding ligands 32, the excess ligands 34 more readily contribute to the transport of carriers between the blue quantum dots 26B than the injection of carriers into the blue quantum dots 26B, and thus more strongly contribute to the generation of reactive current. Accordingly, the blue light-emitting layer 14B of the blue light-emitting element 48B reduces the concentration of the excess ligands 34 that mainly contribute to the generation of reactive current, and more effectively reduces the generation of reactive current in the blue light-emitting element 48B.

Herein, n is the total number of carbon atoms, halogen atoms, group III atoms, group IV atoms, group V atoms, group VI atoms, and hydrogen chains of the excess ligands 34. In this case, a ratio of the number of the excess ligands 34 to the total number of the ligands 30 may be 1/(2n) or less. In this case, the blue light-emitting layer 14B more effectively reduces the generation of reactive current in the blue light-emitting element 48B. Further, when the ratio of the number of the excess ligands 34 to the total number of the ligands 30 is 3/(10n) or less, the blue light-emitting layer 14B more effectively reduces the generation of reactive current in the blue light-emitting element 48B.

The ratio of the number of the excess ligands 34 to the number of the ligands 30 in the blue light-emitting layer 14B may be measured by using, for example, a diffusion ordered spectroscopy (DOSY) technique. The DOSY technique is a composition analysis method of mapping a molecular weight of each molecule and a diffusion coefficient relative to a magnetic field gradient for a mixture including a plurality of types of molecules.

When the DOSY technique is applied to the ligands 30, the measured value of the diffusion coefficient relative to the molecular weight of the excess ligands 34 is higher than the measured value of the diffusion coefficient relative to the molecular weight of the binding ligands 32. Accordingly, a concentration ratio between the binding ligands 32 and the excess ligands 34 can be calculated by calculating, for the blue light-emitting layer 14B, an integrated intensity of a peak on a molecular weight—diffusion constant map obtained by mapping based on the DOSY technique.

Alternatively, the ratio of the number of the excess ligands 34 to the number of the ligands 30 in the blue light-emitting layer 14B may be measured by using, for example, a thermal desorption—gas chromatograph/mass spectrometer (TD-GC/MS) technique. The TD-GC/MS technique is a composition analysis method of locally heated a material surface by a probe including a heat source, adsorbing a volatilized component by an adsorbent, and performing gas phase chromatography and mass spectrometry on the component.

When the TD-GC/MS technique is applied to the ligands 30, the measured value of the volatilization temperature relative to the molecular weight of the excess ligands 34 is lower than the measured value of the volatilization temperature relative to the molecular weight of the binding ligands 32. This is accompanied by a decrease in the volatilization temperature of the excess ligands 34 by a temperature corresponding to the energy consumed for coordination bond formation of the binding ligands 32. Accordingly, the concentration ratio between the binding ligands 32 and the excess ligands 34 can be calculated by individually performing mass spectrometry on the binding ligands 32 and the excess ligands 34 from the difference in the volatilization temperature relative to the molecular weight obtained by the TD-GC/MS technique with respect to the blue light-emitting layer 14B.

By the analysis method described above, the ratio of the number of the excess ligands 34 to the total number of the ligands 30 in the blue light-emitting layer 14B can be calculated from the concentration ratio between the binding ligands 32 and the excess ligands 34. Note that, in a case in which the analysis method described above is applied to the display device 2, the light-emitting layer 14 included in a portion of the light-emitting elements may be analyzed and the measurement result may be applied to the light-emitting layer 14 included in each light-emitting element. In particular, in the TD-GC/MS technique, local heating by a probe is possible, and thus analysis of the light-emitting layer 14 included in a single light-emitting element is possible.

### Comparison of Characteristics of Light-Emitting Elements

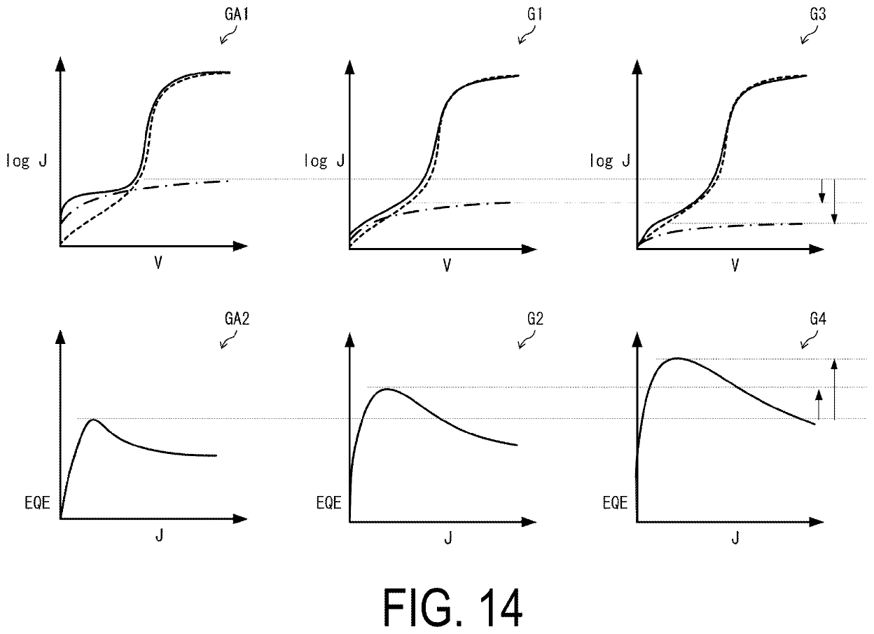

With reference to FIG. 14, the respective characteristics of the blue light-emitting element 6BA according to the comparative embodiment, the blue light-emitting element 6B according to the first embodiment, and the blue light-emitting element 48B according to the present embodiment will be compared and evaluated. The graphs illustrated in FIG. 14 are graphs showing characteristics of the blue light-emitting element according to each embodiment.

The characteristics of the blue light-emitting element 6BA according to the comparative embodiment are illustrated in graph GA1 and graph GA2. The characteristics of the blue light-emitting element 6B according to the first embodiment are illustrated in graph G1 and graph G2. The characteristics of the blue light-emitting element 48B according to the present embodiment are illustrated in graph G3 and graph G4.

The graph GA1, the graph G1, and the graph G3 each show the applied voltage—current characteristics of the blue light-emitting element according to respective embodiments, with the horizontal axis representing the applied voltage and the vertical axis representing the logarithm of the current value. In the graph GA1, the graph G1, and the graph G3, solid lines indicate measured values of the characteristics of the blue light-emitting elements according to the respective embodiments, and dashed lines indicate the characteristics of an ideal diode.

The difference between the characteristics of an ideal diode and the characteristics of an actual light-emitting element occurs due to the generation of a reactive current that does not contribute to light emission in the light-emitting element. In other words, the difference between the ideal current value of the diode and the actual current value of the light-emitting element indicates the magnitude of the reactive current generated in the light-emitting element.

In the graph GA1, the graph G1, and the graph G3, the difference between the current value of the ideal diode and the current value of the blue light-emitting element according to each embodiment is indicated by a dashed-dotted line. In other words, in the graph GA1, the graph G1, and the graph G3, the dashed-dotted line indicates the value of the reactive current generated in the blue light-emitting element according to each embodiment.

In FIG. 14, the values of the reactive current at the applied voltages at which the current value of the reactive current is substantially saturated in the graph GA1, the graph G1, and the graph G3 are compared by dotted lines. As is clear from the comparison between the graph GA1 and the graph G1, the reactive current of the blue light-emitting element 6B according to the first embodiment is reduced compared with that of the blue light-emitting element 6BA according to the comparative embodiment. Furthermore, as is clear from the comparison between the graph G1 and the graph G3, the reactive current of the blue light-emitting element 48B according to the present embodiment is further reduced as compared with that of the blue light-emitting element 6B according to the first embodiment.

The graph GA2, the graph G2, and the graph G4 respectively show values of external quantum efficiencies with respect to values of currents flowing through the blue light-emitting elements according to the respective embodiments, with the horizontal axis representing the current values and the vertical axis representing the external quantum efficiencies. In FIG. 14, maximum values of the external quantum efficiencies in the graph GA2, the graph G2, and the graph G4 are compared by dotted lines. In general, the external quantum efficiency of a light-emitting element is proportional to the luminous efficiency of the light-emitting element.

As is clear from the comparison between the graph GA2 and the graph G2, the blue light-emitting element 6B according to the first embodiment has a high maximum external quantum efficiency compared with that of the blue light-emitting element 6BA according to the comparative embodiment. Furthermore, as is clear from the comparison between the graph G2 and the graph G4, the blue light-emitting element 48B according to the present embodiment has an even higher maximum external quantum efficiency compared with that of the blue light-emitting element 6B according to the first embodiment.

As described above, the blue light-emitting element 6B according to the first embodiment reduces the reactive current and improves the luminous efficiency as compared with the blue light-emitting element 6BA according to the comparative embodiment. Furthermore, the blue light-emitting element 48B according to the present embodiment further reduces the reactive current and further improves the luminous efficiency as compared with the blue light-emitting element 6B according to the first embodiment.

Note that the red light-emitting element 48R and the green light-emitting element 48G according to the present embodiment have the same configuration as that of the blue light-emitting element 48B, except for the luminescent color of the quantum dots included in the light-emitting layer 14. Accordingly, each of the red light-emitting element 48R and the green light-emitting element 48G has the same effect as that of the blue light-emitting element 48B.

### Method for Removing Excess Ligands

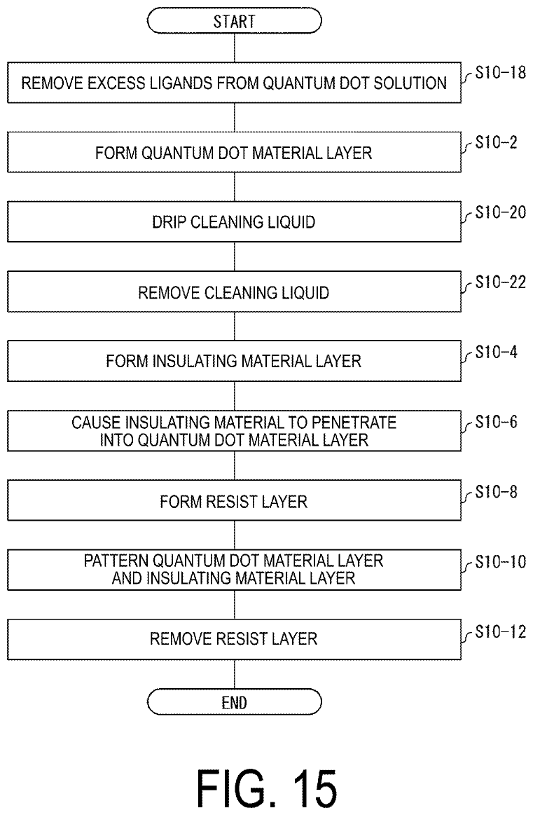

The display device 2 according to the present embodiment can be manufactured by a manufacturing method obtained by changing only the process of forming the light-emitting layer in the method for manufacturing the display device 2 according to the first embodiment. The method for forming the light-emitting layer 14 according to the present embodiment will now be described in more detail with reference to FIG. 15. FIG. 15 is a flowchart for describing the method for forming the light-emitting layer 14 according to the present embodiment.

In the process of forming the blue light-emitting layer 14B according to the present embodiment, prior to step S10-2, the excess ligands 34 are removed from a blue quantum dot solution used for forming the blue quantum dot material layer 36B (step S10-18).

In step S10-18, for example, the blue quantum dot solution is centrifuged. Thus, the blue quantum dot solution is separated by centrifugation into a solution including the blue quantum dots 26B and the binding ligands 32 and a solution including the excess ligands 34. Here, with only the solution including the blue quantum dots 26B and the binding ligands 32 being extracted, a blue quantum dot solution in which the concentration of the excess ligands 34 is reduced is obtained.

Next, the blue quantum dot material layer 36B is formed by the same technique as that in step S10-2 according to the first embodiment. Here, the blue quantum dot material layer 36B is formed by using the solution of the blue quantum dots 26B in which the concentration of the excess ligands 34 was reduced by execution of step S10-18 described above.

Next, a cleaning liquid is dripped onto the blue quantum dot material layer 36B thus formed (step S10-20). The cleaning liquid may include, for example, alcohols or ethers, and may include a solvent in which the ligand 30 is highly soluble. Thus, at least a portion of the excess ligands 34 in the blue quantum dot material layer 36B is released into the cleaning liquid.

Next, the cleaning liquid is removed from the blue quantum dot material layer 36B into which the cleaning liquid was dripped (step S10-22). Step S10-22 may be implemented by, for example, inclining the blue quantum dot material layer 36B together for each substrate 4 and causing the cleaning liquid to flow from the blue quantum dot material layer 36B. In step S10-22, as the cleaning liquid is removed from the blue quantum dot material layer 36B, the excess ligands 34 released in the cleaning liquid are also removed by viscous resistance between the cleaning liquid and the excess ligands 34.

In the above-described process of cleaning the excess ligands 34 nanoscale in size with the cleaning liquid, a viscosity of the cleaning liquid significantly acts on an inertia of the excess ligands 34 due to the size effect. Therefore, the viscous resistance between the excess ligands 34 and the cleaning liquid efficiently acts, and the excess ligands 34 are effectively released into the cleaning liquid. Further, as the number of side chains of the excess ligands 34 increases, the viscous resistance between the excess ligands 34 and the cleaning liquid acts with greater strength, more efficiently discharging the excess ligands 34 with the cleaning liquid. Note that, in the case of removing the excess ligands 34 having a small number of side chains and a relatively low viscous resistance with the cleaning liquid, the cleaning process described above may be repeated a plurality of times.

The blue light-emitting layer 14B according to the present embodiment is obtained by sequentially executing step S10-4 to step S10-12 according to the first embodiment following step S10-22. The red light-emitting layer 14R and the green light-emitting layer 14G may be formed by partially changing the process of forming the blue light-emitting layer 14B described above in accordance with the method described in the first embodiment, and executing the changed process. With the above, the process of forming the light-emitting layer 14 according to the present embodiment can be executed.

The method for forming the blue light-emitting element 6B according to the present embodiment includes a process of reducing the excess ligands 34 from the blue quantum dot material layer 36B. By this formation method, the blue quantum dot layer 22B having a reduced concentration of the excess ligands 34 can be formed. In the method for forming the blue light-emitting element 6B according to the present embodiment, an example in which step S10-18, step S10-20, and step S10-22 are all executed has been described, but no such limitation is intended. For example, the concentration of the excess ligands 34 in the blue quantum dot layer 22B can be reduced by executing any one of step S10-18, step S10-20, and step S10-22.

Note that, in step S10-18 and step S10-22, a portion of the binding ligands 32 are considered detached from the blue quantum dots 26B and removed from the solution of the blue quantum dots 26B. In this case, the excess ligands 34 newly form coordination bonds with the blue quantum dots 26B from which a portion of the binding ligands 32 is detached, forming the binding ligands 32. With the binding ligands 32 and the excess ligands 34 in an equilibrium state with each other as described above, even when a portion of the binding ligands 32 is removed in the process described above, contribution to the reduction in the excess ligands 34 results.

Further, step S10-18, step S10-20, and step S10-22 according to the present embodiment may be applied to the blue quantum dot material layer 36B according to the previous embodiment, and may also be applied to the mixed layer 40B according to the previous embodiment. For example, in the previous embodiment, prior to step S10-14, the excess ligands 34 may be removed from the solution used for forming the mixed layer 40B. Furthermore, in the previous embodiment, after step S10-14, the dripping of the cleaning liquid into the mixed layer 40B and the removal of the cleaning liquid from the mixed layer 40B may be executed. Thus, the blue quantum dot layer 22B and the blue quantum dot layer 46B having a reduced concentration of the excess ligands 34 can be formed by the method for forming the blue light-emitting element 6B according to the previous embodiment.

### Fourth Embodiment

Layered Structure of Quantum Dot Layer and Insulating Layer

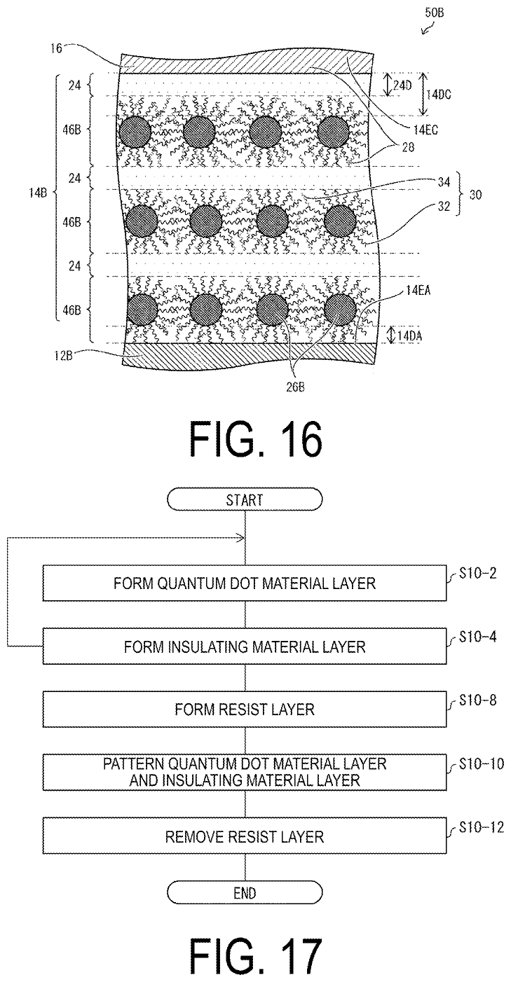

FIG. 16 is an enlarged schematic view illustrating a partial region of a schematic cross section of the display device 2 according to the present embodiment, and is an enlarged view of a position corresponding to the enlarged schematic view of the display device 2 illustrated in FIG. 1. As compared to the display device 2 according to the first embodiment, the display device 2 according to the present embodiment includes a red light-emitting element 50R, a green light-emitting element 50G, and a blue light-emitting element 50B instead of the red light-emitting element 6R, the green light-emitting element 6G, and the blue light-emitting element 6B, respectively. Otherwise, the display device 2 according to the present embodiment has the same configuration as that of the display device 2 according to the first embodiment.

The blue light-emitting element 50B according to the present embodiment, as compared with the blue light-emitting element 6B according to the first embodiment, differs in configuration in that the blue light-emitting layer 14B includes a plurality of the blue quantum dot layers 46B and a plurality of the insulating layers 24 alternately layered. The blue quantum dot layer 46B according to the present embodiment may have the same configuration as that of the blue quantum dot layer 46B according to the second embodiment. Further, the insulating layer 24 according to the present embodiment may have the same configuration as that of the insulating layer 24 according to each embodiment previously described.

Note that FIG. 16 illustrates the blue light-emitting layer 14B including the blue quantum dot layer 46B and the insulating layer 24 in quantities of three each, but no such limitation is intended. For example, the blue light-emitting layer 14B may include the blue quantum dot layer 46B and the insulating layer 24 in quantities of two each or in quantities of four or more each. Further, the thickness 24D of the insulating layer 24 may be the same in at least two layers, or may be different from each other.

In particular, the blue light-emitting layer 14B according to the present embodiment includes the blue quantum dot layer 46B with the end face 14EA on the anode 10 side formed by the end face, on the anode 10 side, of the blue quantum dot layer 46B positioned closest to the anode 10. Furthermore, the blue light-emitting layer 14B includes the insulating layer 24 with the end face 14EC on the cathode 18 side formed by the end face, on the cathode 18 side, of the insulating layer 24 positioned closest to the cathode 18. Therefore, in the present embodiment as well, the gap 14DA is smaller than the gap 14DC.

Otherwise, the blue light-emitting element 50B according to the present embodiment has the same configuration as that of the blue light-emitting element 6B according to the first embodiment.

The blue light-emitting element 50B reduces the occurrence of a reactive current and the occurrence of electron excess in the blue light-emitting layer 14B for the same reasons as those described in the first embodiment. Therefore, the blue light-emitting element 50B improves the luminous efficiency and extends the lifetime.

Furthermore, the blue light-emitting layer 14B according to the present embodiment includes the insulating layer 24 between the two blue quantum dot layers 46B as well. Therefore, the blue light-emitting layer 14B can reduce a reactive current propagating from a certain blue quantum dot layer 46B to another blue quantum dot layer 46B. Accordingly, the blue light-emitting element 50B according to the present embodiment can further reduce the generation of the reactive current in the blue light-emitting layer 14B.

Note that, in the present embodiment, an example is given in which the blue light-emitting layer 14B includes a plurality of the blue quantum dot layers 46B that do not include the insulating material 28, but no such limitation is intended. For example, the blue light-emitting layer 14B according to the present embodiment may include a plurality of the blue quantum dot layers 22B including the insulating material 28 described in each of the embodiments described above, instead of the blue quantum dot layer 46B. With this configuration, the blue light-emitting element 50B can more efficiently reduce the reactive current propagating between the blue quantum dots 26B.

Furthermore, as compared with the blue light-emitting element 50B, the red light-emitting element 50R and the green light-emitting element 50G according to the present embodiment have the same configuration except for the luminescent color of the quantum dots included in the light-emitting layer 14. Accordingly, each of the red light-emitting element 50R and the green light-emitting element 50G has the same effect as that of the blue light-emitting element 50B.

### Repetition of Film Formation Process

The display device 2 according to the present embodiment can be manufactured by a manufacturing method obtained by changing only the process of forming the light-emitting layer in the method for manufacturing the display device 2 according to the first embodiment. The method for forming the light-emitting layer 14 according to the present embodiment will now be described in more detail with reference to FIG. 17. FIG. 17 is a flowchart for describing the method for forming the light-emitting layer 14 according to the present embodiment.

In the process of forming the blue light-emitting layer 14B according to the present embodiment, first, step S10-2 and step S10-4 according to the first embodiment are alternately executed a plurality of times to obtain a layered structure of the blue quantum dot material layer 36B and the insulating material layer 38. Therefore, a process of curing the insulating material 28 included in the blue quantum dot material layer 36B and the insulating material layer 38 may be implemented every time the pair of steps S10-2 and S10-4 is executed.

In the present embodiment, the number of times step S10-2 and step S10-4 are executed is determined in accordance with the number of layers of the blue quantum dot layer 46B and the insulating layer 24 to be formed. After execution of step S10-2 and step S10-4 is completed the prescribed number of times, step S10-8 to step S10-12 according to the first embodiment are sequentially executed. In step S10-10 according to the present embodiment, the plurality of blue quantum dot material layers 36B and the insulating material layer 38 may be patterned at once.

With the above, the blue light-emitting layer 14B according to the present embodiment is obtained. The red light-emitting layer 14R and the green light-emitting layer 14G may be formed by partially changing the process of forming the blue light-emitting layer 14B described above in accordance with the method described in the first embodiment, and executing the changed process. With the above, the process of forming the light-emitting layer 14 according to the present embodiment can be executed.

The process of forming the blue light-emitting layer 14B according to the present embodiment does not include the process of forming the mixed layer 40B. For example, the formation process does not include a process of causing a portion of the insulating material 28 of the insulating material layer 38 to penetrate into the blue quantum dot material layer 36B, and does not include a process of forming the mixed layer 40B from a solution including the blue quantum dot material layer 26B and the insulating material 28. Therefore, by the process of forming the blue light-emitting layer 14B according to the present embodiment, the blue light-emitting layer 14B can be formed more simply.

However, the process of forming the blue light-emitting layer 14B according to the present embodiment is not limited to the processes described above. For example, in the process of forming the blue light-emitting layer 14B described above, the penetration process of causing a portion of the insulating material 28 in the insulating material layer 38 to penetrate into the blue quantum dot material layer 36B may be executed every time the pair of steps S10-2 and S10-4 is executed. The penetration process may be executed by the same technique as that in step S10-6 in the first embodiment. By this formation process, the blue light-emitting layer 14B including a plurality of the blue quantum dot layers 22B including the insulating material 28 can be formed.

### Fifth Embodiment

Other Form of Light-Emitting Element

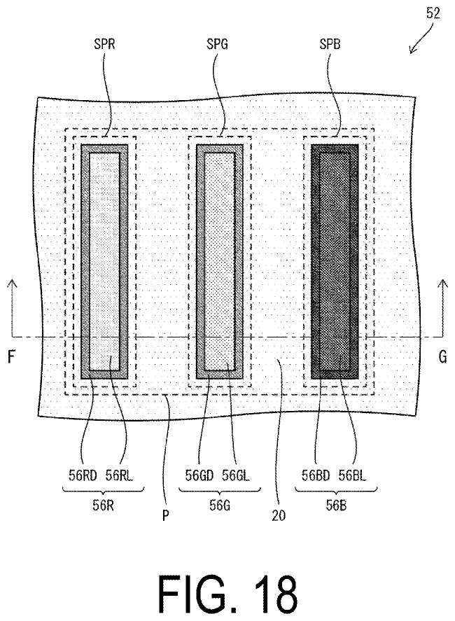

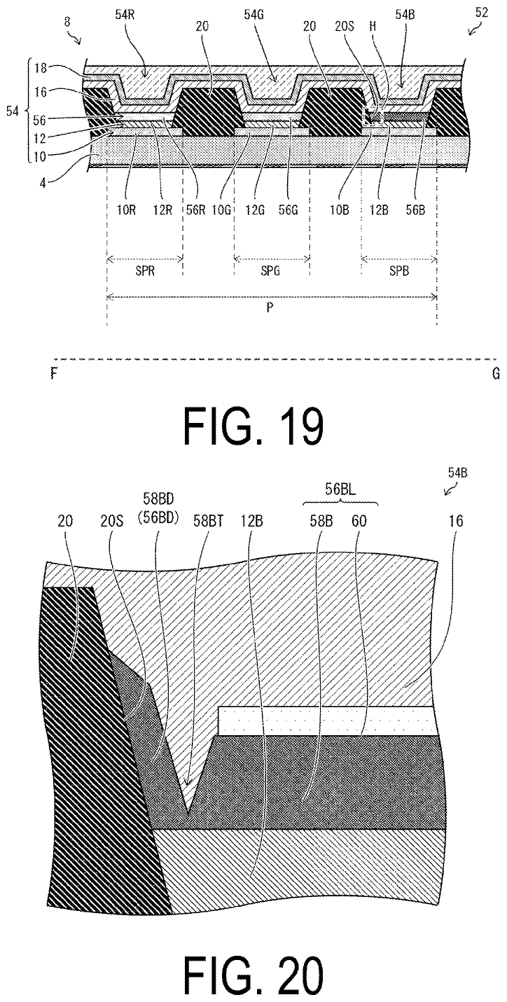

FIG. 18 is an enlarged schematic view of a partial region of the display region DA of a display device 52 according to the present embodiment, and is an enlarged view illustrating a position corresponding to the enlarged schematic view illustrated in FIG. 3. FIG. 19 is a schematic cross-sectional view of the display device 2 according to the present embodiment, and is a cross-sectional view taken along line F-G in FIG. 18. FIG. 20 is an enlarged schematic view of a cross section of the display device 2 according to the present embodiment, and is an enlarged view of a region H illustrated in FIG. 19. Note that, in FIG. 18, the sealing layer 8, the electron transport layer 16, and the cathode 18 are not illustrated as in FIG. 3.

The display device 52 according to the present embodiment, as compared with the display device 2 according to each embodiment described above, differs in configuration only in including a light-emitting element layer 54 instead of the light-emitting element layer 6. The light-emitting element layer 54, as compared with the light-emitting element layer 6 according to each embodiment described above, differs in configuration only in including a light-emitting layer 56 instead of the light-emitting layer 14.

In the present embodiment, the light-emitting element layer 54 includes, as light-emitting elements, a red light-emitting element 54R in the red subpixel SPR, a green light-emitting element 54G in the green subpixel SPG, and a blue light-emitting element 54B in the blue subpixel SPB.

In the present embodiment as well, the light-emitting layer 56 is separately formed on a subpixel-by-subpixel basis. In particular, in the present embodiment, the light-emitting layer 56 includes a red light-emitting layer 56R that emits red light, a green light-emitting layer 56G that emits green light, and a blue light-emitting layer 56B that emits blue light.

Accordingly, in the present embodiment, the red light-emitting element 54R is composed of the anode 10R, the hole transport layer 12R, the red light-emitting layer 56R, the electron transport layer 16, and the cathode 18. Further, the green light-emitting element 54G is composed of the anode 10G, the hole transport layer 12G, the green light-emitting layer 56G, the electron transport layer 16, and the cathode 18. Furthermore, the blue light-emitting element 54B is composed of the anode 10B, the hole transport layer 12B, the blue light-emitting layer 56B, the electron transport layer 16, and the cathode 18.

Like the light-emitting layer 14, the light-emitting layer 56 is a layer that emits light as a result of an occurrence of recombination between the holes transported, via the hole transport layer 12, from the anode 10 and the electrons transported, via the electron transport layer 16, from the cathode electrode 18. However, the light-emitting layer 56 may include, as a luminescent body, a fluorescent material, a phosphorescent material, or the like in addition to a quantum dot material, and may include an organic material in addition to an inorganic material. For example, each light-emitting element according to the present embodiment may be a QLED element, or may be an organic light-emitting diode (OLED) element.

The light-emitting element layer 54 is separated into the red light-emitting element 54R, the green light-emitting element 54G, and the blue light-emitting element 54B by the bank 20 formed on the substrate 4. Further, the red light-emitting layer 56R, the green light-emitting layer 56G, and the blue light-emitting layer 56B are in contact with the side surface 20S of the bank 20.

As illustrated in FIG. 18, the red light-emitting layer 56R according to the present embodiment includes a main light-emitting portion 56RL and an outer edge portion 56RD. Further, the green light-emitting layer 56G according to the present embodiment includes a main light-emitting portion 56GL and an outer edge portion 56GD. Furthermore, the blue light-emitting layer 56B according to the present embodiment includes the main light-emitting portion 56BL and the outer edge portion 56BD. The outer edge portion 56RD, the outer edge portion 56GD, and the outer edge portion 56BD, in plan view of the substrate 4, are disposed at positions surrounding the main light-emitting portion 56RL, the main light-emitting portion 56GL, and the main light-emitting portion 56BL, respectively. Therefore, each of the outer edge portion 56RD, the outer edge portion 56GD, and the outer edge portion 56BD is in contact with the side surface 20S of the bank 20.

### Main Light-Emitting Layer and Protection Layer

The main light-emitting portion and the outer edge portion of the light-emitting layer 56 according to the present embodiment will now be described in more detail with reference to an enlarged schematic view of the vicinity of an interface between the bank 20 and the light-emitting layer 56 illustrated in FIG. 20. FIG. 20, in particular, is an enlarged schematic view illustrating the vicinity of the interface between the bank 20 and the blue light-emitting layer 56B of the blue light-emitting element 54B of the display device 2 according to the present embodiment, and is an enlarged view illustrating the region H illustrated in FIG. 19. Herein, unless otherwise specified, the main light-emitting portion 56RL and the main light-emitting portion 56GL have the same configuration as that of the main light-emitting portion 56BL, and the outer edge portion 56RD and the outer edge portion 56GD have the same configuration as that of the outer edge portion 56BD, except for materials.

The main light-emitting portion 56BL includes a main light-emitting layer 58B including a blue light-emitting material included in the blue light-emitting layer 56B, and a protection layer 60 covering an upper face of the main light-emitting layer 58B, in this order from the substrate 4 side. The protection layer 60 may include the insulating material 28 described above, and may have the same configuration as that of the insulating layer 24, for example. When the protection layer 60 includes the insulating material 28, the protection layer 60 is an insulating layer having insulating properties. For example, the protection layer 60 is a layer including at least a material that is chemically more stable than the light-emitting material included in the main light-emitting layer 58B, such as an inorganic material. Note that the main light-emitting portion 56RL and the main light-emitting portion 56GL according to the present embodiment have the same configuration as that of the main light-emitting portion 56BL except that these include a light-emitting material layer including a red light-emitting material and a light-emitting material layer including a green light-emitting material, respectively.

On the other hand, the outer edge portion 56BD includes a deactivation layer 58BD and does not include the protection layer 60. The deactivation layer 58BD is in contact with the side surface 20S of the bank 20 and is continuous with the main light-emitting layer 58B of the main light-emitting portion 56BL with a thin film portion 58BT, having a thickness thinner than the surrounding portion, interposed therebetween.

However, the deactivation layer 58BD need not be continuous with the main light-emitting portion 56BL, and may be formed as a separate body. In other words, the blue light-emitting layer 56B may not be formed between the main light-emitting portion 56BL and the outer edge portion 56BD, and the main light-emitting portion 56BL and the outer edge portion 56BD may be separated by the electron transport layer 16.

The deactivation layer 58BD includes a material in which the light-emitting material included in the main light-emitting layer 58B is deactivated by oxidation, moisture permeation, physical damage, or the like. Therefore, the deactivation layer 58BD has a low luminous efficiency compared to the main light-emitting layer 58B. Otherwise, the deactivation layer 58BD may have the same configuration as that of the main light-emitting layer 58B. Note that the outer edge portion 56RD and the outer edge portion 56GD according to the present embodiment have the same configuration as that of the outer edge portion 56BD except for including a deactivation layer including a material in which the red light-emitting material is deactivated and a deactivation layer including a material in which the green light-emitting material is deactivated, respectively.

### Method for Forming Light-Emitting Material Layer and Protection Layer

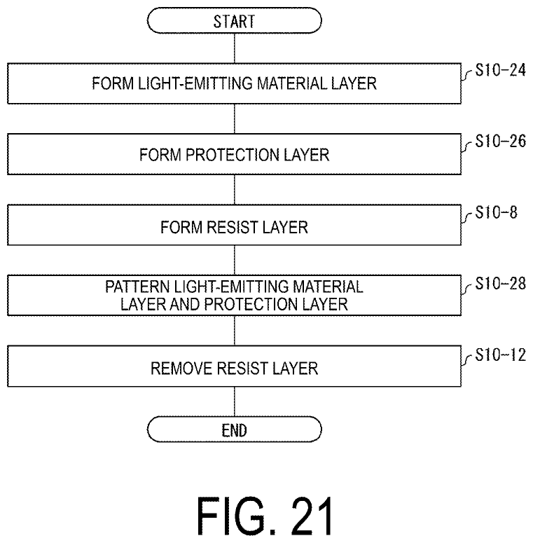

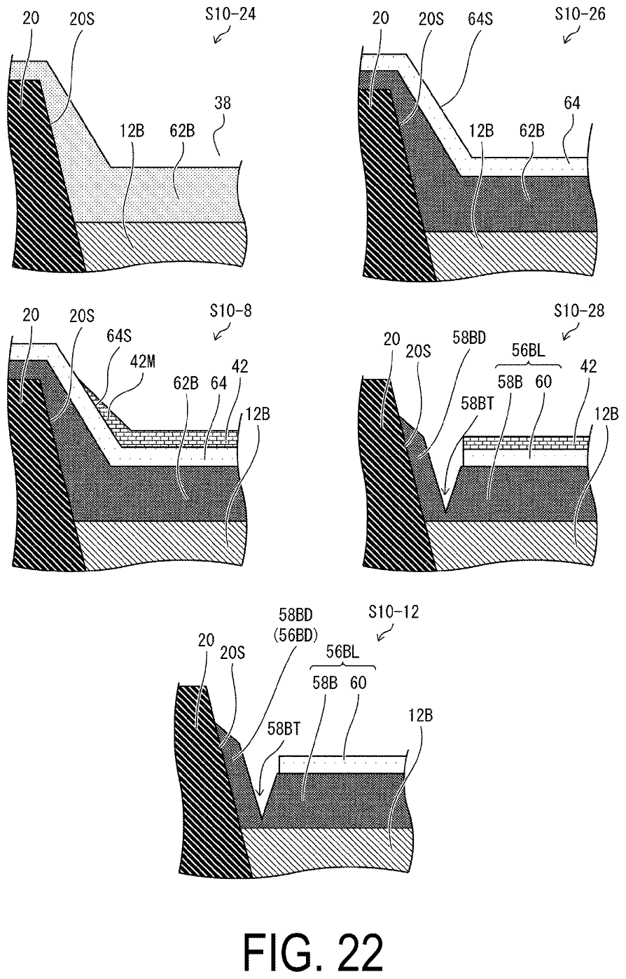

The display device 52 according to the present embodiment can be manufactured by the same method as the method for manufacturing the display device 2 according to each of the embodiments described above by changing only the formation process of the light-emitting layer. The method for forming the light-emitting layer 56 according to the present embodiment will now be described in more detail with reference to FIG. 21 and FIG. 22. Hereinafter, the method for forming the light-emitting layer 56 in the present embodiment will be described by using the method for forming the blue light-emitting layer 56B as a representative. FIG. 21 is a flowchart for describing the method for forming the light-emitting layer 56 according to the present embodiment. FIG. 22 illustrates process cross-sectional views of the vicinity of the side surface 20S of the bank 20 positioned in the blue subpixel SPB in the process of forming the light-emitting layer 56 according to the present embodiment. Note that each process cross-sectional view illustrated in FIG. 22 illustrates a cross section at a position corresponding to the cross section illustrated in FIG. 20.

In the process of forming the blue light-emitting layer 56B according to the present embodiment, first, a light-emitting material layer 62B is formed by forming a thin film including a blue light-emitting material on the entire surface of an upper layer overlaying the hole transport layer 12B and the bank 20 (step S10-24). In other words, in step S10-24, the light-emitting material layer 62B is formed not only for the blue subpixel SPB but also for the red subpixel SPR and the green subpixel SPG. Therefore, the light-emitting material layer 62B is formed on the side surface 20S of the bank 20 as well.

Next, a material including the protection layer 60 is formed on the light-emitting material layer 62B, thereby forming the protection layer 64 (step S10-26). The protection layer 64 is also formed on the entire upper face of the light-emitting material layer 62B. Therefore, on an upper face of the protection layer 64, an inclined face 64S reflecting the inclination of the side surface 20S of the bank 20 is formed around the blue subpixel SPB.

Note that the light-emitting material layer 62B and the protection layer 64 may be formed by applying a solution including the insulating material 28 by an application method using a coater, for example. Alternatively, the light-emitting material layer 62B and the protection layer 64 may be formed by, for example, vapor deposition or an electrodeposition method.

Next, the resist layer 42 is formed in an upper layer overlying the protection layer 64 for each blue subpixel SPB by the same technique as that in step S10-8 according to the embodiments described above. In the present embodiment as well, a portion of the resist layer 42 formed at a position adjacent to the inclined face 64S creeps up the inclined face 64S due to the meniscus effect. Accordingly, after execution of step S10-8, the light-emitting material layer 62B and the protection layer 64 are covered with the outer edge portion 42M of the resist layer 42 at a position overlapping the side surface 20S of the bank 20 in plan view of the substrate 4, the outer edge portion 42M being relatively thin.

Next, the light-emitting material layer 62B and the protection layer 64 are etched by an appropriate etching method to pattern the light-emitting material layer 62B and the protection layer 64 (step S10-28). The light-emitting material layer 62B and the protection layer 64 may be etched by using, for example, the etching material used in step S10-10 according to the embodiments described above. As a result, the light-emitting material layer 62B having an island shape and the protection layer 64 are formed for each blue subpixel SPB, and become the main light-emitting layer 58B and the protection layer 60, respectively.

In the present embodiment as well, when step S10-8 is completed, the resist layer 42 is also thinly formed as the outer edge portion 42M on the inclined face 64S of the protection layer 64 positioned around the blue subpixel SPB. Therefore, by execution of step S10-28, a portion of the light-emitting material layer 62B remains on the side surface 20S of the bank 20 without being etched. However, the light-emitting material layer 62B at this position is exposed to the etching material under the same circumstances as those described in the first embodiment.

In particular, the etching in the step S10-28 is executed by dry etching or wet etching. In this case, the blue light-emitting material remaining on the side surface 20S of the bank 20 and included in the light-emitting material layer 62B exposed to the etching material is deteriorated and deactivated by oxidation or the like. Therefore, when step S10-28 is completed, the deactivation layer 58BD is formed on the side surface 20S of the bank 20.

Next, the resist layer 42 is removed from the protection layer 64 by the same technique as that in step S10-12 according to the previous embodiment. Thus, the main light-emitting portion 56BL, including the main light-emitting layer 58B and the protection layer 60, and the outer edge portion 56BD, including the deactivation layer 58BD, are obtained, thereby completing the process of forming the blue light-emitting layer 56B.

The red light-emitting layer 56R and the green light-emitting layer 56G may be formed by partially changing the process of forming the blue light-emitting layer 56B described above, and executing the changed process. For example, in the process of forming the red light-emitting layer 56R and the green light-emitting layer 56G, the blue light-emitting material included in the light-emitting material layer 62B in the process of forming the blue light-emitting layer 56B is changed to a red light-emitting material and a green light-emitting material, respectively. Further, in the process of forming the red light-emitting layer 56R and the green light-emitting layer 56G, the position where the resist layer 42 is formed in step S10-8 described above is changed to positions overlapping the red subpixel SPR and the green subpixel SPG, respectively, in plan view of the substrate 4. With the above, the process of forming the light-emitting layer 56 according to the present embodiment can be executed.

In step S10-8 according to the present embodiment, the protection layer 64 is formed in an upper layer overlying the light-emitting material layer 62B. Therefore, even when the material included in the protection layer 64 is deteriorated by contact with the developing solution described above, the protection layer 64 can reduce contact between the light-emitting material layer 62B and the developing solution described above. Further, the protection layer 64 may include a chemically stable material as compared with the light-emitting material included in the light-emitting material layer 62B. In this case, even in a case in which the developing solution used for patterning the resist layer 42 comes into contact with the protection layer 64, the deterioration of the protection layer 64 is reduced as compared with the deterioration of the light-emitting material of the light-emitting material layer 62B when the developing solution comes into contact with the light-emitting material layer 62B. Accordingly, the protection layer 64 can protect the light-emitting material layer 62B from the developing solution used for patterning the resist layer 42, and reduces deterioration of the blue light-emitting material included in the light-emitting material layer 62B.

Further, in step S10-28 according to the present embodiment, the patterning of the light-emitting material layer 62B and the protection layer 64 is executed by dry etching or wet etching. Therefore, by step S10-28, at the position covered with the outer edge portion 42M of the resist layer 42, the deactivation layer 58BD, including the deactivated blue light-emitting material, and the outer edge portion 56BD, including the deactivation layer 58BD, are formed.

Thus, the outer edge portion 56BD of the blue light-emitting element 54B formed by the formation method described above, with the included blue light-emitting material being deactivated, has a luminous efficiency that is significantly reduced. Accordingly, by forming the blue light-emitting element 54B by the formation method described above, abnormal light emission of the outer edge portion 56BD can be reduced.

Therefore, the blue light-emitting element 54B can make the carriers injected into the blue light-emitting layer 56B efficiently contribute to the light emission of the main light-emitting portion 56BL, thereby improving the luminous efficiency of the main light-emitting portion 56BL. Further, the blue light-emitting element 54B includes the outer edge portion 56BD having a low luminous efficiency at an outer edge of the main light-emitting portion 56BL. Therefore, the blue light-emitting element 54B can reduce the light emission intensity at or near the boundary with the other light-emitting elements. As a result, the display device 2 including the blue light-emitting element 54B can reduce color mixing between subpixels, improving the display quality.

Furthermore, in step S10-12 according to the present embodiment, the protection layer 60 is formed in an upper layer overlying the main light-emitting layer 58B. For this reason, the protection layer 60 can protect the main light-emitting layer 58B from the remover used for removing the resist layer 42, thereby reducing deterioration of the blue light-emitting material.

Note that the protection layer 60 according to the present embodiment is an insulating layer including the insulating material 28. Therefore, in the main light-emitting portion 56BL in which the protection layer 60 is provided at a position in contact with the end face of the main light-emitting layer 58B on the cathode 18 side, the electron excess in the main light-emitting layer 58B is reduced due to the circumstances described in the embodiments described above. Accordingly, the blue light-emitting element 54B according to the present embodiment improves the luminous efficiency of the blue light-emitting layer 56B.

The methods for forming the red light-emitting element 54R and the green light-emitting element 54G according to the present embodiment can be executed by only changing each light-emitting material and the formation position of each light-emitting layer 56 in the method for forming the blue light-emitting element 54B. Accordingly, the methods for forming the red light-emitting element 54R and the green light-emitting element 54G according to the present embodiment also achieve the same effects as those of the method for forming the blue light-emitting element 54B.

### Sixth Embodiment

PTL 2 expresses the view that, as the coordination compound of the quantum dot decreases, luminescence decreases, leading to device deterioration.

However, according to detailed analysis of the electrical characteristics and the light-emission characteristics of the light-emitting element including the quantum dot by the present inventors, it was found that the coordination compound of the quantum dot must be reduced to the extent possible in order to improve the luminous efficiency of the light-emitting element.

That is, it was found that the current flowing through the light-emitting element is composed of (1) a component according to the Shockley equation, (2) an ohmic component, and (3) a nonlinear component, and among them, (2) the ohmic component and (3) the nonlinear component are reactive currents which do not contribute to radiative recombination. In particular, it was found that the nonlinear component accounts for most of the reactive current, and the luminous efficiency (EQE (external quantum efficiency)) can be improved by suppressing this nonlinear component. The nonlinear component of the current flowing through the light-emitting element is conducted through coordination compounds connecting adjacent quantum dots and separated excess coordination compounds. Accordingly, to improve the luminous efficiency, the coordination compounds of the quantum dots in the light-emitting element must be reduced to the extent possible.

On the other hand, a coordination compound is necessary for inactivating defects present on the surfaces of the quantum dots and serving as carrier traps and non-emitting centers to disperse the quantum dots in a solvent. Therefore, to improve the light-emission characteristics of the light-emitting element, it is necessary to solve the trade-off related to the contents of the coordination compound.

Unless the coordination compound of the quantum dot is reduced as described in PTL 2, the reactive current, including the nonlinear component of the current, conducted through the excess coordination compounds connecting adjacent quantum dots and the separated coordination compounds, cannot be reduced, and therefore the luminous efficiency of the light-emitting element cannot be improved.

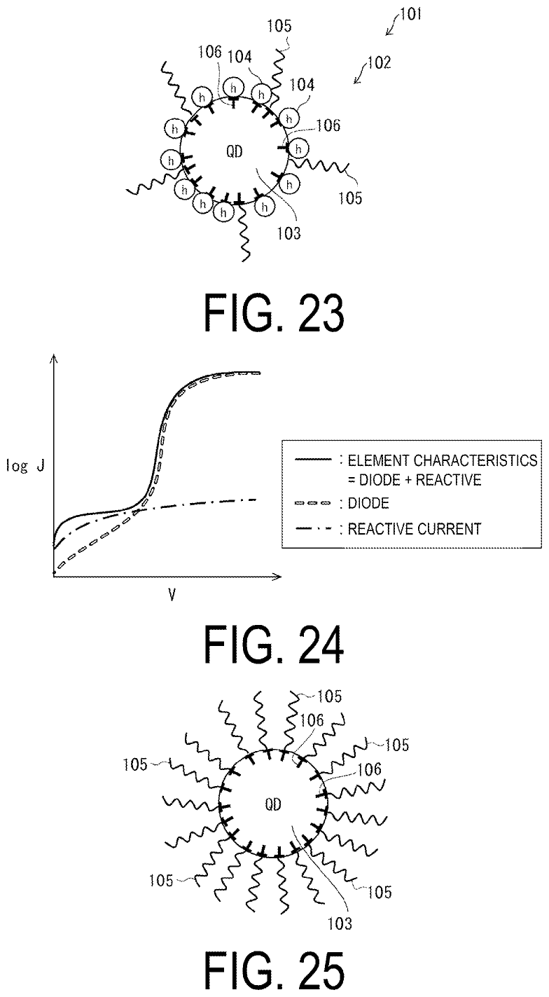

FIG. 23 is a schematic view of a quantum dot 103 included in a light-emitting layer 102 of a light-emitting element 101 according to the sixth embodiment.

The light-emitting layer 102 (quantum dot layer) includes the quantum dot 103, a halogen element 104, and a ligand 105 (coordination compound) that can coordinate to the quantum dot 103. The ligand 105 includes a compound having one or more and n or less (where n is a plural number) carbon-hydrogen bonds, or a compound having n chain structures with different elements bonded at any two coordination positions of an element that can substantially have a coordination number of four or greater. A mass ratio between the ligand 105 and the quantum dot 103 is 0.5 or less, and may be 5/(10×n) or less.

The halogen element 104 inactivates a defect 106 on a surface of the quantum dot 103.

The halogen element 104 preferably is present at or near the surface of the quantum dot 103. The defect 106 on the surface of the quantum dot 103 can be inactivated by the halogen element 104 present at or near the surface of the quantum dot 103. Then, with a mass ratio between the ligand 105 and the quantum dot 103 being 0.5 or less, a mass ratio of the ligand 105 is reduced while maintaining the dispersibility of the quantum dot 103 in the solvent, thereby making it possible to reduce the reactive current flowing through the ligand 105. As a result, it is possible to improve an external quantum efficiency of the quantum dot 103.

The halogen element 104 may have a density from 10¹⁵ cm⁻³ to 10²⁰ cm⁻³. The defect 106 on the surface of the quantum dot 103 can be inactivated by the halogen element 104 having a density from 10¹⁵ cm⁻³ to 10²⁰ cm⁻³. Then, with a mass ratio between the ligand 105 and the quantum dot 103 being 0.5 or less, a mass ratio of the ligand 105 is reduced while maintaining the dispersibility of the quantum dot 103 in the solvent, thereby making it possible to reduce the reactive current flowing through the ligand 105. As a result, it is possible to improve an external quantum efficiency of the quantum dot 103.

FIG. 24 is a graph showing typical electrical characteristics of the light-emitting element and analysis results thereof.

The electrical characteristics illustrated in FIG. 24 can be decomposed into a current injected into the quantum dots according to an exp(E) by the Shockley equation, a leakage current flowing into a small amount according to Ohm's law proportional to the voltage, and a reactive current proportional to the n-th power of the voltage (where n is a real number or an integer other than 1). It has been found that a reactive current proportional to the n-th power of the voltage is, in most cases, a space-charge-limited current proportional to the square of the voltage and the −3rd power of the layer thickness, or a current proportional to an even higher power of the voltage. The origin of this space-charge-limited current arises from the fact that the ligands 105 coordinated to the quantum dots 103 or the ligands 105 separated from the quantum dots 103 bind the quantum dots 103 adjacent to each other. Therefore, a first means for improving the EQE of a quantum dot light-emitting diode (QLED) reduces the amount of the ligands 105.

FIG. 25 is a schematic view of the quantum dot 103 according to a comparative example.

The defect 106, which is crystalline, is present on the surface of the quantum dot 103 and, as long as this defect 106 is active, the defect 106 inhibits carrier injection into the quantum dot 103 and radiative recombination. In the related art, this defect 106 is inactivated and thus does not affect carrier injection and radiative recombination by causing the ligand 105 to coordinate to the quantum dot 103. However, as described above, the ligand 105 is also a cause of generating a reactive current which does not contribute to the light emission of the quantum dot 103. Further, the ligand 105 is necessary for dispersing the quantum dots 103 in the solvent of the quantum dot colloidal solution, making it difficult to reduce the amount of the ligands 105 to date due to demands for manufacturing the light-emitting element, such as application or printing of the quantum dot colloidal solution.

In the present embodiment, the halogen element 104 is introduced to solve the contradictory factors of a reducing the reactive current in relation to the ligands 105 and meeting the requirements for manufacture. Then, as illustrated in FIG. 23, for the functions of inactivation and dispersibility of the defect 106 concentrated in the ligands 105, the function of inactivation of the defect 106 is separated into the halogen element 104, and the function of dispersibility of the quantum dot colloidal solution into the solvent is separated into the ligands 105. Thus, both inactivation of the defect 106 and dispersibility of the quantum dot colloidal solution in the solvent are achieved.

In the configuration of the present embodiment, first, the defect 106 on the surface of the quantum dot 103 is inactivated by using the halogen element 104. As the halogen element 104, for example, a small amount of an appropriate halogen compound need only be added after the shell is formed in the manufacture of the quantum dot 103. Alternatively, a halogen compound may be added when the ligand 105 is caused to coordinate to the quantum dot 103. The halogen element 104 is a group 7 element in the periodic table and is stabilized as a closed shell upon acquiring one electron, making it likely to be selectively bonded to a vacancy of a group VI or group V element separated from the shell constituting the surface of the quantum dot 103.

Further, in the halogen element 104, a K shell, an L shell, an M shell, and an N shell are sequentially closed in the order of F, Cl, Br, and I. As a result, inner-shell shielding is stronger and an ion radius is larger in this order, and I, Br, Cl, and F tend to readily bond to a defect in the shell in this order. Accordingly, although depending on the shell material as well, F is generally most strongly bonded and stable, and thus is suitable for the configuration of the present embodiment.

As described above, the halogen element 104 preferably includes F. The defect 106 on the surface of the quantum dot 103 can be inactivated by the halogen element 104 which has the highest effect of inactivating the defect 106.

The halogen element 104 preferably includes at least one of Cl, Br, or I. The defect 106 on the surface of the quantum dot 103 can be inactivated by at least one halogen element 104 of Cl, Br, and I.

In general, a group II-VI compound such as ZnS constituting the shell of the quantum dot 103 of a core-shell type readily causes defects due to loss of a group VI element such as S, and a group III-V compound such as AlAs or AlN readily causes loss of a group V element such as As or N. The halogen element 104 is suitable for inactivating these vacancies.

The defect 106 on the surface of the quantum dot 103 has a surface density from 10¹⁰ cm⁻² to 10¹⁴ cm⁻² in correspondence with a defect density per volume of 10¹⁵ cm⁻³ to 10²¹ cm⁻³ in a bulk state, and a volume density of the halogen element 104 required to inactivate the defect 106 on the surface is desirably in the order of from 10¹⁵ cm⁻³ to 10²¹ cm⁻³. As long as this volume density is within this range, the defect 106 on the surface can be sufficiently inactivated to allow for the ligands 105 to coordinate and improve the characteristics of the QLED. When the density of the halogen element 104 is lower than the range described above, the defect 106 on the surface of the quantum dot 103 cannot be sufficiently inactivated, which is not preferable.

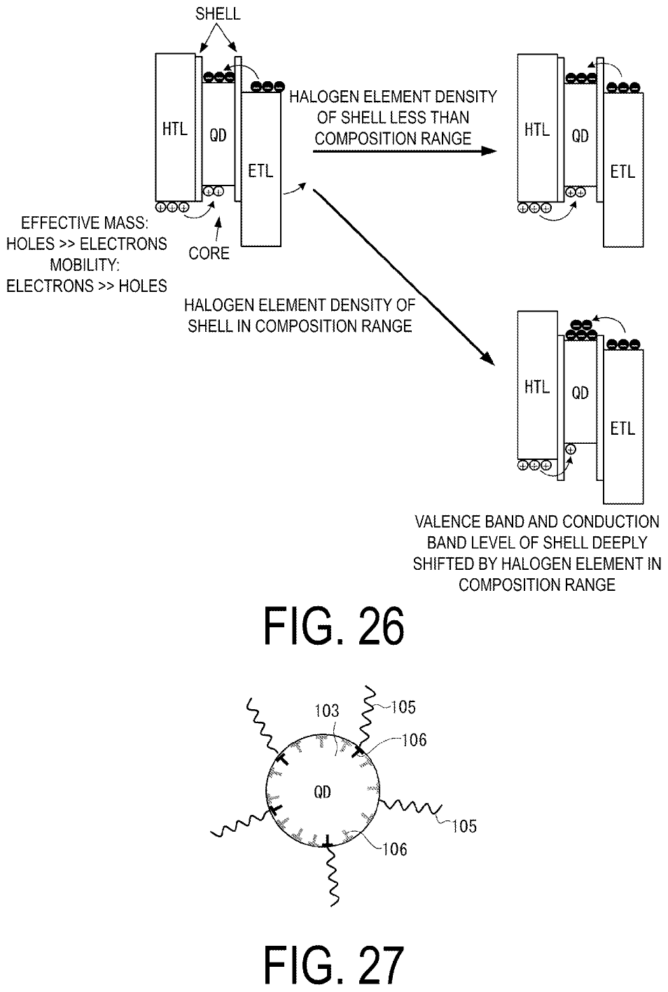

FIG. 26 is a schematic view of the halogen density, level of quantum dots, and carrier injection.

On the other hand, when the density of the halogen element 104 is higher than the range described above, the density practically reaches a level of being considered part of the composition of the shell material of the quantum dot 103. In a case in which the halogen element 104 constitutes the composition of the compound constituting the quantum dot 103, because the energy of the p-orbital of the halogen element 104 is large, the valence band formed by the p-orbital of the constituent elements shifts in a direction in which the level deepens when the halogen element 104 is included as part of the composition, and the conduction band level also shifts in a direction in which the level deepens in conjunction therewith, as illustrated in FIG. 26. In this case, the barrier when holes are injected into the quantum dot 103 is high and the barrier when electrons are injected into the quantum dot 103 is low, changing the carrier balance of the quantum dot 103 in the direction of electron excess and thus decreasing the EQE of the QLED, which is not preferable.

Thus, the halogen element 104 is captured by the defect 106 on the shell surface, acquires an electron, and is stabilized, thereby inactivating the defect 106 on the surface without coordination of the ligand 105. Next, the ligand 105 is caused to coordinate to the defect 106 not inactivated by the halogen element 104 on the surface of the quantum dot 103, and dispersed in a solvent such as octane by the same technique as in the related art to complete the quantum dot colloidal solution.

The ligand 105 is desirably a compound having at least one or more and n or less (where n is a plural number less than or equal to 50) carbon-hydrogen bonds, or a compound having chain structures with different elements bonded at any two coordination positions of an element that can substantially have a coordination number of four.

Given n as the number of chain structures including a carbon-hydrogen bond, a mass ratio between the ligand 105 and the quantum dot 103 is preferably from 1/(10×n) to 5/(10×n), more preferably from 1/(10×n) to 3/(10×n). When the number is less than this range, problems such as aggregation and precipitation occur when the quantum dots 103 are dispersed in the solvent, which is not preferable. Conversely, when the number exceeds this range, the reactive current, which does not contribute to light emission, increases when the light-emitting layer 102 of a QLED is used, which is not preferable.

The mass ratio described above can be measured by, for example, the following measurement method.

It is only necessary to qualitatively analyze the molecular structure and the molecular weight and quantify the mass of each molecule. Therefore, the mass of each component can be quantified by integrating a peak signal of each component of a total ion chromatogram (TIC) by using gas chromatography/mass spectrometry (GC/MS) and determining the area. The molecular structure of each component can be identified by analyzing the mass spectrum. Further, if thermal desorption—gas chromatography/mass spectrometry (TD-GC/MS) is used, it is possible to analyze the component and mass in consideration of the volatilization temperature of the molecule and the binding energy with the quantum dot.

The ligand 105 preferably includes a compound having three or more carbon-hydrogen bonds or a compound having three or more chain structures. With a compound having three or more carbon-hydrogen bonds or a compound having three or more chain structures, the distance between the quantum dots 103 can be appropriately maintained, and energy transfer due to resonance (fluorescence resonance energy transfer (FRET)) between adjacent quantum dots 103 can be suppressed. When there are two or less, the adjacent quantum dots 103 are too close to each other, increasing the FRET.

The ligand 105 preferably includes an inorganic compound, an organic compound, or a perfluoro compound. With inclusion of an inorganic compound, an organic compound, or a perfluoro compound, it is possible to reduce the mass ratio of the ligand 105 while maintaining the dispersibility of the quantum dot 103 in the solvent, thereby reducing the reactive current flowing through the ligand 105.

FIG. 27 is a schematic view of the quantum dot 103 according to another comparative example. The mass ratio between the ligand 105 and the quantum dot 103 is 0.5 or less. Therefore, the reactive current flowing through the ligands 105 is reduced while the dispersibility of the quantum dots 103 in the solvent is maintained. However, because the halogen element 104 is not preset at or near the surface of the quantum dot 103, most of the defects 106 of the quantum dot 103 are in an active state. For this reason, when a light-emitting element is formed by using the quantum dots 103, although the reactive current can be reduced, the state of carrier injection into the quantum dots 103 is deteriorated and the EQE is reduced.

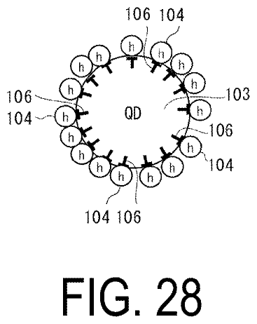

FIG. 28 is a schematic view of the quantum dot 103 according to yet another comparative example. The halogen element 104 is present at or near the surface of the quantum dot 103, making it possible to inactivate the defect 106 of the quantum dot 103. However, the ligand 105 is not present, and thus the quantum dot 103 cannot be dispersed in a solvent, and a light-emitting element cannot be manufactured.

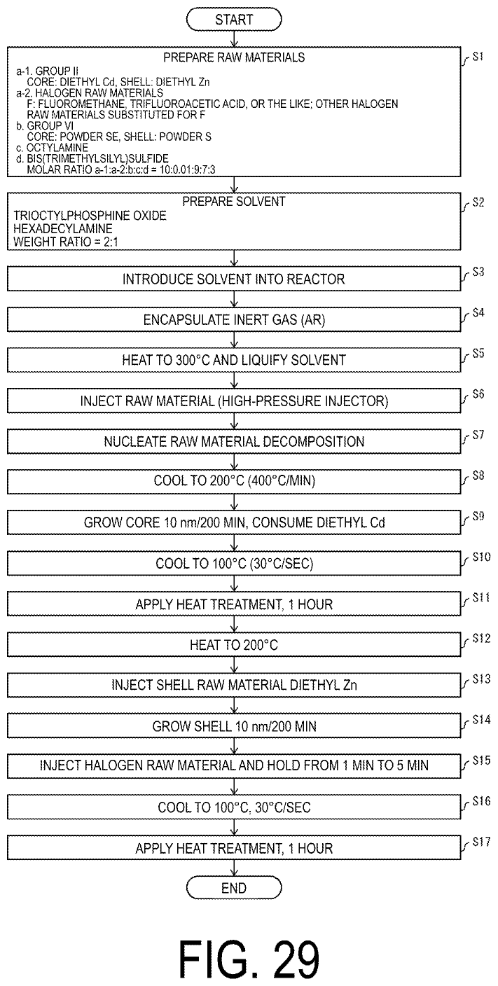

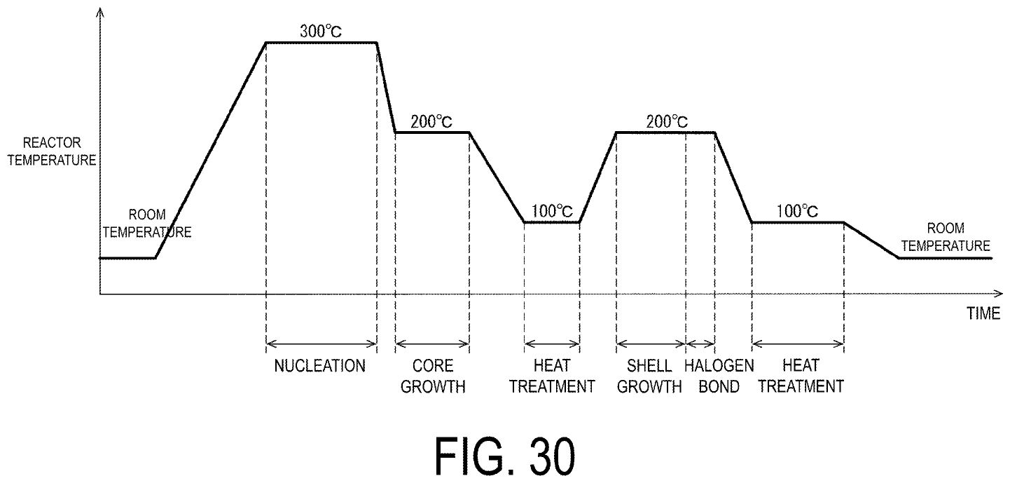

FIG. 29 is a flowchart illustrating a method for manufacturing a quantum dot colloidal solution in which the quantum dots 103 according to the sixth embodiment are dispersed in a solvent. FIG. 30 is a graph showing a procedure for manufacturing the quantum dot colloidal solution described above.

First, raw materials of the quantum dots 103 of a core-shell type, raw materials of the halogen element 104, and the like are prepared (step S1). Then, raw materials of the solvent in which the quantum dots 103 are to be dispersed are prepared (step S2). Next, the prepared raw materials of the solvent are charged into a reactor (step S3). Subsequently, an inert gas such as Ar is sealed in the reactor (step S4).

Then, a temperature of the reactor is increased to 300° C. to liquefy the raw materials of the solvent (step S5). Next, the materials of the quantum dots 103 are injected into the reactor by a high-pressure injector (step S6). Subsequently, the materials of the quantum dots 103 are decomposed to form nuclei (step S7).

Then, the temperature of the reactor is decreased to 200° C. at 400° C./min (step S8). Next, the cores of the quantum dots 103 grow at 10 nm/200 min and diethyl Cd is consumed (step S9).

Subsequently, the temperature of the reactor is decreased to 100° C. at 30° C./sec (step S10). Then, heat treatment is executed for one hour (step S11).

Next, the temperature of the reactor is increased to 200° C. (step S12). Subsequently, materials of the shell of the quantum dots 103 are injected, and diethyl Zn is consumed (step S13). The shells then grow at 10 nm/200 min (step S14). Next, raw materials of the halogen element 104 are injected and held for 1 min to 5 min (step S15).

Subsequently, the temperature of the reactor is decreased to 100° C. at 30° C./sec (step S16). Then, heat treatment is executed for one hour (step S17).

A method for manufacturing a quantum dot colloidal solution includes adding the halogen element 104 at or near the surface of a quantum dot 103, causing the ligands 105 to coordinate to the surface of the quantum dot 103 and thus bringing a mass ratio between the ligand 105 and the quantum dot 103 to 0.5 or less, and dispersing the quantum dots 103 with the halogen element 104 added and the ligands 105 coordinated into a solvent to obtain the quantum dot colloidal solution.

The defect 106 on the surface of the quantum dot 103 can be inactivated by the halogen element 104 added at or near the surface of the quantum dot 103. Then, with the mass ratio between the ligand 105 and the quantum dot 103 being 0.5 or less, the dispersibility of the quantum dot 103 in the solvent can be maintained.

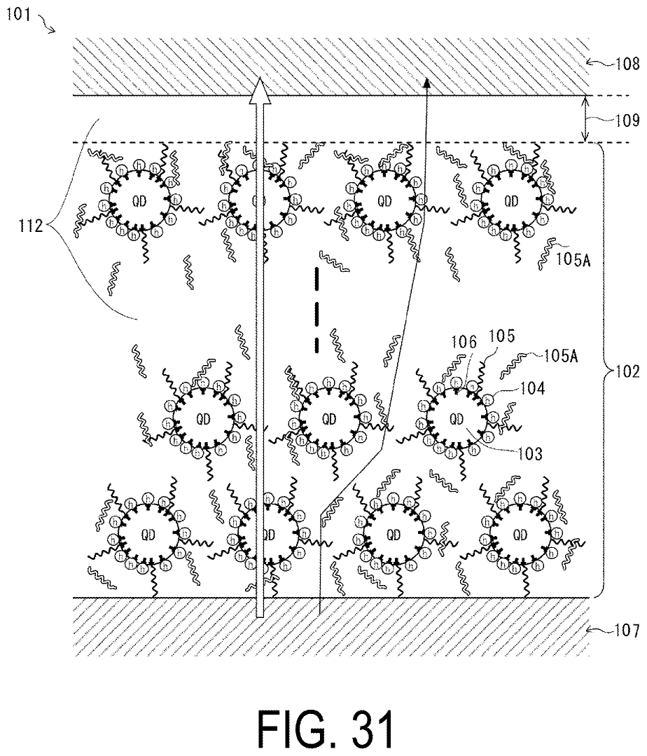

FIG. 31 is a cross-sectional view of the light-emitting layer 102, a hole transport layer 107, and an electron transport layer 108 formed in the light-emitting element 101 according to the sixth embodiment.

The light-emitting element 101 includes the light-emitting layer 102, the hole transport layer 107 (first charge transport layer) in contact with the light-emitting layer 102, and the electron transport layer 108 (second charge transport layer) formed on a side of the light-emitting layer 102 opposite to the hole transport layer 107.

The light-emitting layer 102 includes the quantum dot 103, the halogen element 104, the ligand 105 that can coordinate to the quantum dot 103, and an insulating material 112. The ligand 105 includes a compound having one or more and n or less (where n is a plural number) carbon-hydrogen bonds, or a compound having n chain structures with different elements bonded at any two coordination positions of an element that can substantially have a coordination number of four or greater. The mass ratio between the ligand 105 and the quantum dot 103 is 0.5 or less.

The light-emitting element 101 further includes an insulating layer 109 formed between the light-emitting layer 102 and the electron transport layer 108. The insulating layer 109 includes the insulating material 112.

The light-emitting layer 102, on the side facing the electron transport layer 108, is adjacent to the electron transport layer 108 with the insulating material 112 interposed therebetween. The hole transport layer 107 is in contact with the light-emitting layer 102, and thus charge injection from the hole transport layer 107 to the light-emitting layer 102 is not inhibited, and charge injection from the electron transport layer 108 to the light-emitting layer 102 is suppressed by the insulating material 112. As a result, the external quantum efficiency of the quantum dot 103 can be further improved.

Charge injection from the electron transport layer 108 to the light-emitting layer 102 is suppressed by the insulating layer 109 formed between the light-emitting layer 102 and the electron transport layer 108. As a result, the external quantum efficiency of the quantum dot 103 can be further improved.

Preferably, the insulating layer 109 is amorphous and includes at least one of a glass-based material, a tetrafluoroethylene-based material, or a silicone-based material. The insulating layer 109, being amorphous and including at least one of a glass-based material, a tetrafluoroethylene-based material, or a silicone-based material, suppresses charge injection from the electron transport layer 108 to the light-emitting layer 102.

The insulating layer 109 preferably has a light transmittance of 80% or greater in the visible light region. The insulating layer 109 having a light transmittance of 80% or greater in the visible light region suppresses charge injection from the electron transport layer 108 to the light-emitting layer 102.

The insulating layer 109 preferably includes an ether-based, a perfluoro-based, or a hydrocarbon-based solvent. The ether-based, perfluoro-based, or hydrocarbon-based solvent reinforces suppression of charge injection from the electron transport layer 108 to the light-emitting layer 102.

A thickness of the insulating layer 109 is preferably 5 nm or less. With the thickness of the insulating layer 109 being 5 nm or less, a tunneling current flowing through the quantum dot 103 is maintained.

When the quantum dot 103 configured as illustrated in FIG. 23 is used in the light-emitting layer 102 of a QLED, desirably, as illustrated in FIG. 31, a more effective layered structure is achieved by, first, the hole transport layer 107 and the light-emitting layer 102 being in contact with each other to inhibit hole injection and, second, the electron transport layer 108 and the light-emitting layer 102 not being in contact with each other to suppress electron injection. This is in consideration of suppression of the reactive current that does not contribute to light emission, and in consideration of the fact that a QLED having a known configuration generally has electron excess and a significantly poor carrier balance.

Hole injection equal to or greater than that of a known structure is maintained by the first layer configuration described above, and electron injection is suppressed by the second configuration described above. For the injection of electrons, the insulating layer 109 made of an inorganic or organic or metal oxide may be provided at an interface between the electron transport layer 108 and the light-emitting layer 102, and need only have a thickness from 2 nm to 5 nm. The reactive current depends not only on excess ligands but also on the −3rd power of the layer thickness, and therefore a significant effect can be obtained by increasing, even slightly, a total thickness of the layers transporting the current. For example, if the total thickness of the light-emitting layer 102 and the insulating layer 109 is increased by 10%, the reactive current decreases by 30%. The insulating layer 109 exceeding a thickness of 5 nm suppresses the tunneling of the current flowing through the quantum dot 103, and is therefore not preferred.

The effects described above can be further enhanced by removing excess ligands 105A in the light-emitting layer 102. Here, the excess ligands 105A refers to ligands not coordinated to the surfaces of the quantum dots 103 and randomly distributed in the light-emitting layer 102. According to the configuration of the present embodiment, although the ligands 105 coordinated to the quantum dots 103 are reduced even in the colloidal solution state, because the bonds between the ligands 105 and the quantum dots 103 are not very strong, the ligands are dissociated by viscous resistance during formation of the light-emitting layer 102 or by heat energy during curing, generating the excess ligands 105A in the light-emitting layer 102.

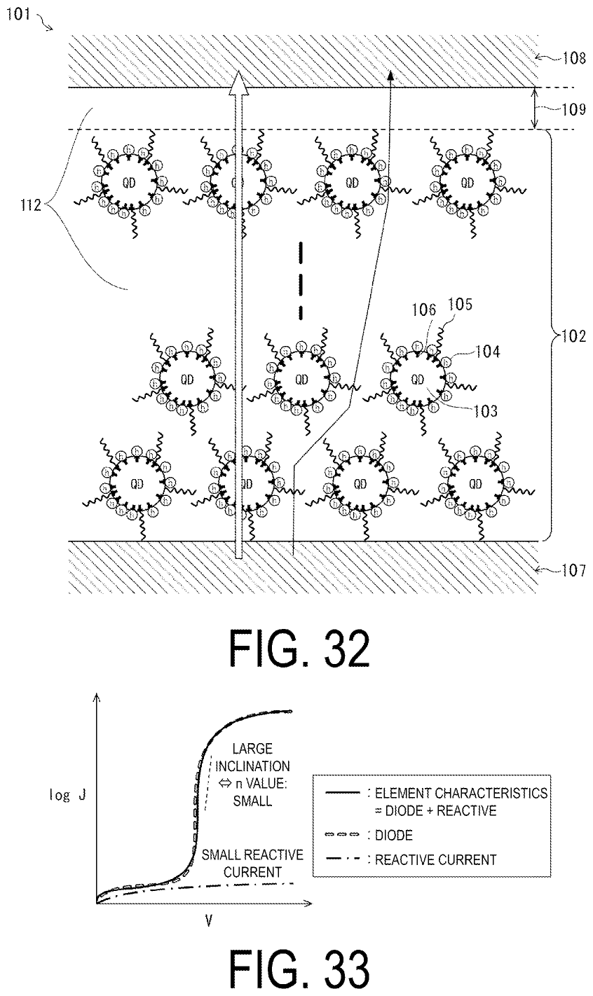

FIG. 32 is a cross-sectional view of the light-emitting element 101 obtained by discharging the excess ligands 105A from the light-emitting layer 102.

When the excess ligands 105A are in contact with each other along a layer thickness direction of the light-emitting layer 102, a reactive current flows in the layer thickness direction through the excess ligands 105A, decreasing the EQE. Therefore, after the light-emitting layer 102 is formed, for example, alcohol or ether is dripped to discharge the excess ligands 105A from the light-emitting layer 102, whereby the reactive current can be further suppressed. This configuration is illustrated in FIG. 32.

As long as the reactive current is suppressed with the configuration described above, it is possible to not only improve the EQE but also reduce heat loss, thereby suppressing thermal deterioration of the light-emitting element 101 due to energization and deterioration of organic materials due to charge transport, making it possible to realize high reliability.

A method for manufacturing the light-emitting element 101 according to the present embodiment includes forming the light-emitting layer 102 on the hole transport layer 107 by using a quantum dot colloidal solution manufactured by the method for manufacturing a quantum dot colloidal solution according to the present embodiment, removing the excess ligands 105A by applying a solvent to the light-emitting layer 102 after the formation, and performing heat treatment on the light-emitting layer 102 with the excess ligands 105A removed.

The defect 106 on the surface of the quantum dot 103 can be inactivated by the halogen element 104 added at or near the surface of the quantum dot 103. Then, with the mass ratio between the ligand 105 and the quantum dot 103 being 0.5 or less and the excess ligands 105A being removed, the reactive current flowing through the ligands 105 can be reduced. As a result, it is possible to improve the external quantum efficiency of the quantum dot 103.

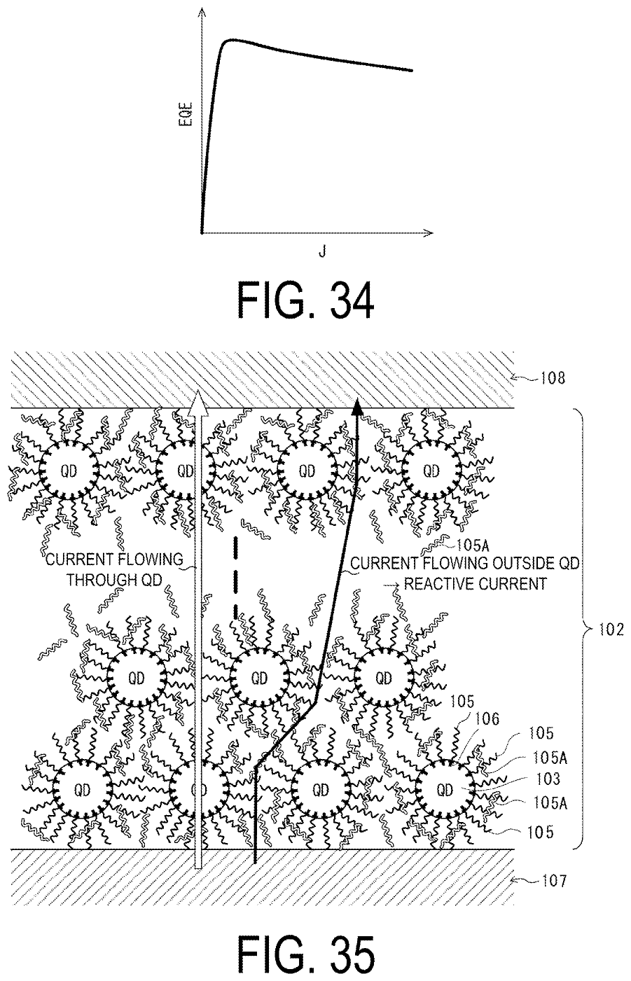

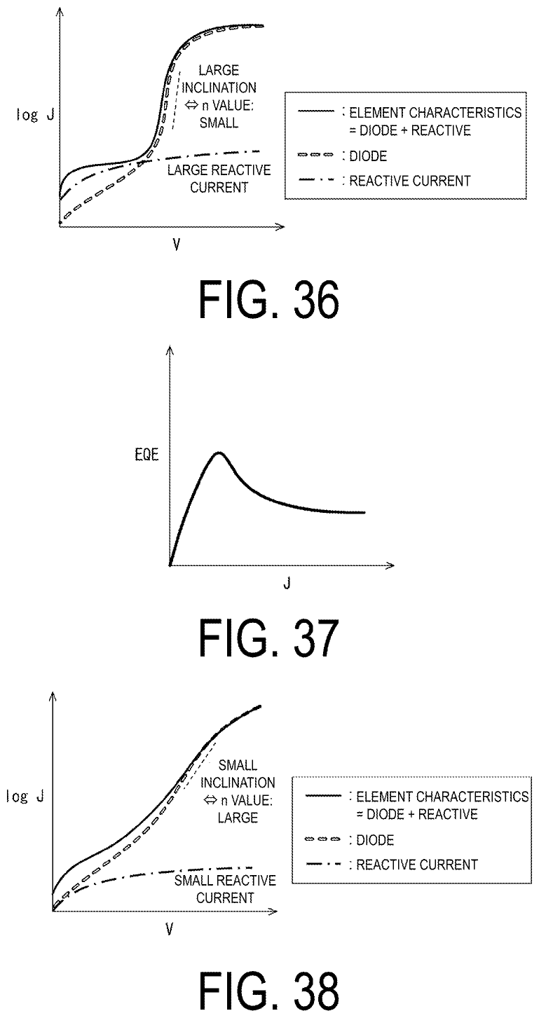

FIG. 33 is a graph showing characteristics of the light-emitting element 101. FIG. 34 is a graph showing other characteristics of the light-emitting element 101. FIG. 35 is a cross-sectional view of the light-emitting layer 102, the hole transport layer 107, and the electron transport layer 108 formed in a light-emitting element according to a comparative example. FIG. 36 is a graph showing characteristics of the light-emitting element described above. FIG. 37 is a graph showing other characteristics of the light-emitting element described above.

The light-emitting layer 102 of the light-emitting element according to the comparative example includes the quantum dots and the excess ligands 105A described above with reference to FIG. 25. As shown in FIG. 36, in the light-emitting element according to the comparative example, a slope of the current relative to the applied voltage increases, decreasing the n value, and the current flows through the excess ligands 105A outside the quantum dots 103, resulting in a large reactive current.

On the other hand, in the light-emitting element 101 illustrated in FIG. 31, the mass ratio between the ligand 105 and the quantum dot 103 is 0.5 or less and thus, as shown in FIG. 33, the slope of the current relative to the voltage applied to the light-emitting element 101 increases, decreasing the n value, and the reactive current included in the current flowing through the light-emitting layer 102 is reduced. Then, as shown in FIG. 34, the EQE of the light-emitting element 101 is improved over the EQE according to the comparative example shown in FIG. 37.

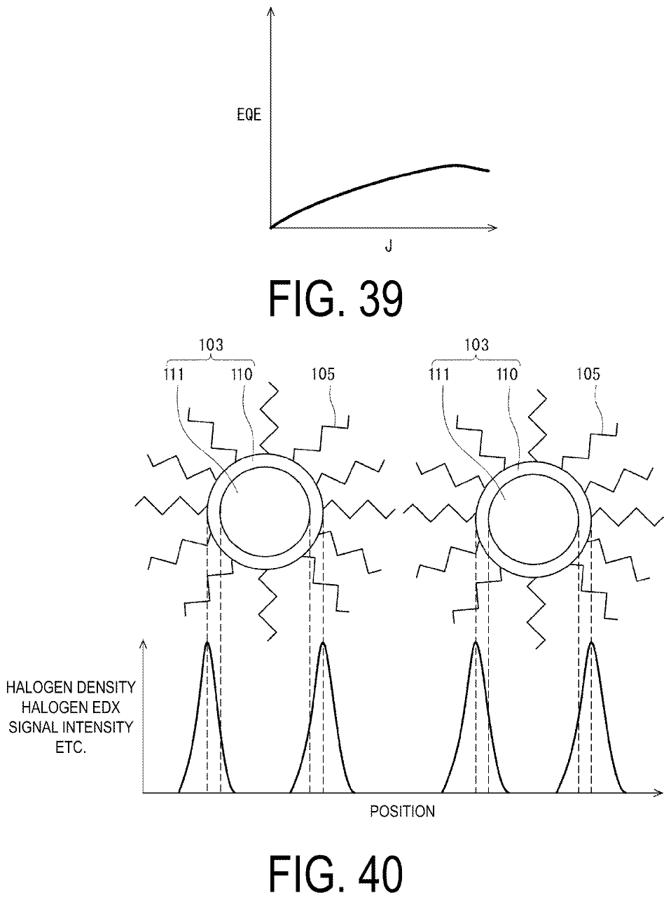

FIG. 38 is a graph showing characteristics of the light-emitting element including the quantum dots 103 according to the other comparative example. FIG. 39 is a graph showing other characteristics of the light-emitting element described above.

The quantum dot 103 according to the other comparative example described above with reference to FIG. 27 has a small amount of the ligands 105, making the reactive current relatively small as illustrated in FIG. 38. However, because the halogen element 104 is not present at or near the surface of the quantum dot 103, most of the defects 106 of the quantum dot 103 are in an active state. As illustrated in FIG. 38, the slope of the current relative to the applied voltage is small and the n value is large. Then, as illustrated in FIG. 39, the EQE is low.

FIG. 40 is a view for describing the halogen element 104 present at or near the surface of the quantum dot 103 according to the sixth embodiment.

The halogen element 104 (FIG. 23) is present at or near the surface of the quantum dot 103. Then, the quantum dot 103 includes a core 111 and a shell 110 formed around the core 111.

A distance between the halogen element 104 and the surface of the quantum dot 103 is less than or equal to a distance corresponding to a thickness of the shell 110. That is, the halogen element 104 being present at or near the surface of the quantum dot 103 means that the halogen element 104 is present within a range from a position inwardly separated from a surface of the shell 110 by a distance corresponding to one-half the thickness of the shell 110 in a radial direction of a cross section of the quantum dot 103 to a position outwardly separated from the surface of the shell 110 by a distance corresponding to one-half the thickness of the shell 110 through the surface of the shell 110.

In this case, when a cross-sectional transmission electron microscope (TEM) image (high-resolution image) of the quantum dot 103 is analyzed by energy dispersive X-ray spectroscopy (EDX), a peak of an EDX signal from the halogen element 104 is present within the range described above, as illustrated in FIG. 40.

The defect 106 on the surface of the quantum dot 103 can be inactivated by the halogen element 104 present at a position where the distance to the surface of the quantum dot 103 is equal to or less than the distance corresponding to the thickness of the shell 110.

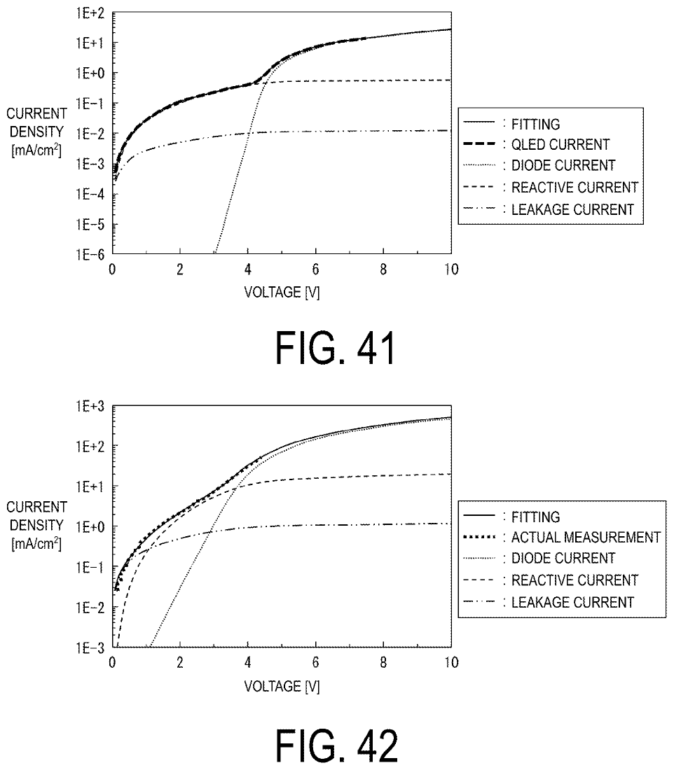

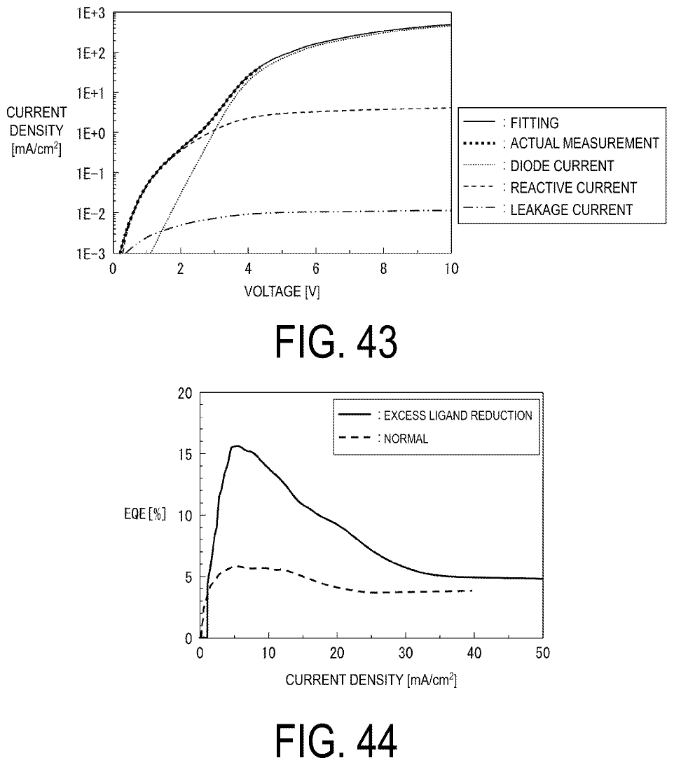

FIG. 41 is a graph for describing details of electrical characteristics of the light-emitting element 101 according to the sixth embodiment. FIG. 42 is a graph for describing details of electrical characteristics of the light-emitting element according to the comparative example. FIG. 43 is a graph for describing details of electrical characteristics of the light-emitting element according to the other comparative example.

A diode current density J_{D}, a reactive current density Jᵣ, and a leakage current density Jₗ are expressed by the following equations.

$${J}_{D} = \frac{1}{S} {I}_{0} [ exp \{ \frac{qV}{nkT} \} - 1 ] \qquad [ Expression 1 ]$$

$${J}_{r} = \frac{1}{S} {k}_{r} \cdot {V}^{nr} \qquad [ Expression 2 ]$$

$${J}_{1} = \frac{1}{S} \frac{V}{{R}_{1}} \qquad [ Expression 3 ]$$

Where,
V: Voltage [V] applied to light-emitting element,
S: Pixel area (area into which current is injected) [cm²],
I₀: Reverse saturation current [mA],
q: Elementary charge [C],
n: Diode coefficient,
k: Boltzmann constant [J/K],
T: Temperature [K],
kᵣ: First reactive current density coefficient [mA·V^{-nr}/cm²] (typically proportional to the dielectric constant, the carrier mobility, and the thickness-³ of the medium),
nr: Second reactive current density coefficient (typically 2), and
Rₗ: Shunt resistance of light-emitting element (typically 1 MΩ or greater).

J₀, kᵣ, nᵣ, and Rₗ described above are determined so as to reproduce the voltage-current density characteristics of the light-emitting element. Normally, the shunt resistance is sufficiently high and the leakage current density is on the order of μA/cm², and therefore the light-emission characteristics are not affected (in a case in which a short circuit occurs between layers or between electrodes, a large leakage current flows, affecting the light-emission characteristics).

The diode current density J_{D} represents a current density flowing through the light-emitting layer 102 of the QLED and injected into the quantum dot 103, and is a component contributing to light emission.

The reactive current density Jᵣ represents a current density flowing through the light-emitting layer 102 of the QLED, but not flowing through the ligand 105 linked in the thickness direction of the light-emitting layer 102 nor injected into the quantum dot 103. Components of this reactive current density Jᵣ do not contribute to light emission.

As shown in FIG. 41, FIG. 42, and FIG. 43, in the light-emitting element 101 including the quantum dot 103 according to the embodiment illustrated in FIG. 23, the slope of the current density relative to the applied voltage was larger and the reactive current was smaller than those of the light-emitting element 101 including the quantum dot 103 according to the comparative example described above with reference to FIG. 25 and FIG. 27.

FIG. 44 is a graph showing other characteristics of the light-emitting element 101 according to the sixth embodiment and the light-emitting element 101 according to the comparative example.

As shown in FIG. 44, the light-emitting element 101 in which the excess ligands 105A were reduced by 30% by dripping methanol and spinning to discharge the excess ligands 105A after formation of the light-emitting layer 102 exhibited a higher EQE than that of the light-emitting element 101 in which the excess ligands 105A were not discharged. Note that the ligand density was quantified by time-of-flight secondary ion mass spectrometry (TOF-SIMS).

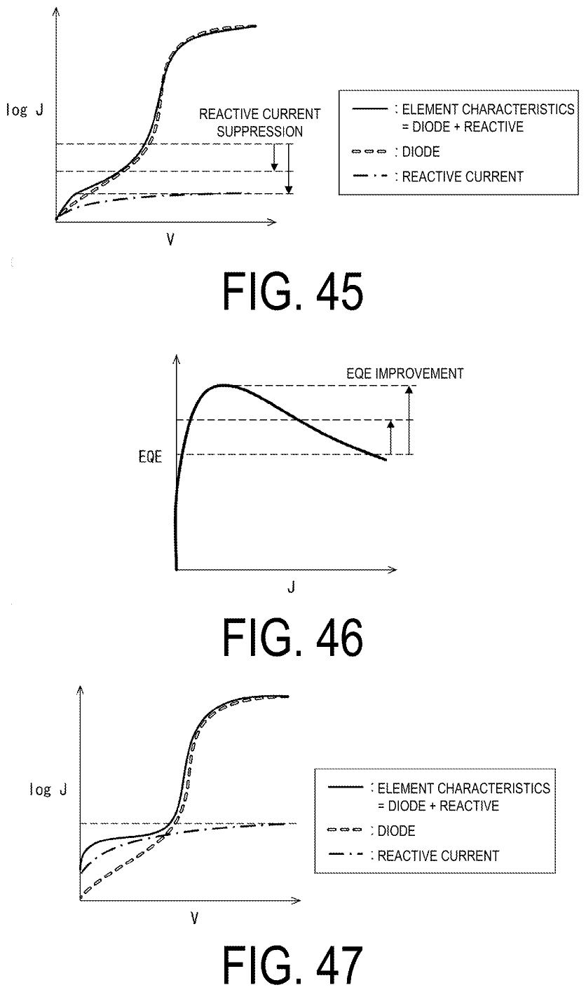

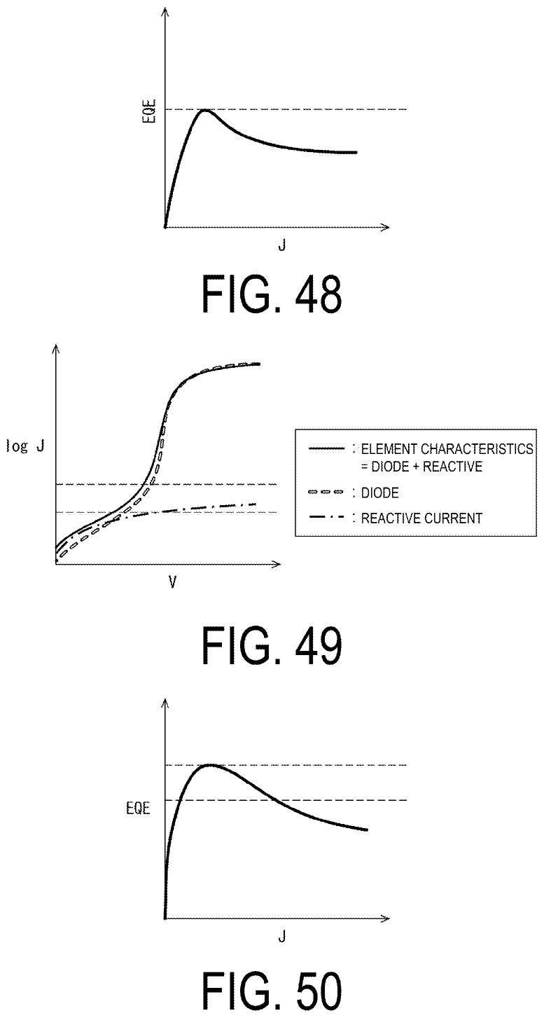

FIG. 45 is a graph showing characteristics of the light-emitting element 101 obtained by discharging the excess ligands 105A. FIG. 46 is a graph showing other characteristics of the light-emitting element 101 described above. FIG. 47 is a graph showing characteristics of the light-emitting element 101 according to the comparative example. FIG. 48 is a graph showing other characteristics of the light-emitting element 101 according to the comparative example. FIG. 49 is a graph showing other characteristics of the light-emitting element 101 according to the other comparative example.

The light-emitting element 101 illustrated in FIG. 31 has fewer ligands 105 than the light-emitting element including the quantum dots according to the comparative example described above with reference to FIG. 25, thereby reducing the reactive current and improving the EQE as shown in FIG. 49 and FIG. 50.

Then, as shown in FIG. 45 and FIG. 46, in the light-emitting element 101 from which the excess ligands 105A illustrated in FIG. 32 were discharged, the reactive current is further reduced and the EQE is further improved.

TABLE 1

| | | Analytical | Detected | Analysis result | |
|---|---|---|---|---|---|
| Analysis item | | technique | components | Sample A | Sample B |
| Particles | Particle size, | SEM•TEM | Cd, Se, Zn, S | About 10 nm, tetrahedral | |
| | shape, element | EDS•STEM | | shape, Se distributed in | |
| | distribution | | | center | |
| | Elemental | XPS | Cd, Se, Zn, S | Difference between samples | |
| | composition of | (atomic %) | | | |
| | main components | Chemical analysis | Cd, Se, Zn, S | Difference between samples | |
| | | (mg/ml) | | | |
| | Ligand | TD-GC/MS | | Detected | |
| | | | | (Detection of different | |
| | | | | components in both | |
| | | | | samples) | |
| | Bonding state of | XPS | Cd | Difference in Cd bonding | |
| | particle surface | (Bonding state) | | state between samples A | |
| | | | | and B | |
| | | TOF-SIMS | CdS, SO | Detected | Not detected |
| | | (Minor | | | |
| | | component) | | | |
| Dispersion | Organic | GC/MS | Hydrocarbon | Not detected | Detected |
| liquid | impurities | LC/MS | Alkylamide | | |
| | | | Fatty acid ester | | |
| | | | Alkylphosphine | | |
| | | | Alkylamine | Trace amount | Detected |
| | | | | detected | |
| | Particle size | SP-ICP-MS | Cd | Distributed | Little bias |
| | distribution | | | toward larger | |

| | | | |
|---|---|---|---|
| Light absorption | Spectrophotometer | — | Difference in suction |
| characteristics | | | strength near 300 nm |

The configuration related to the quantum dot 103, the halogen element 104, the ligand 105, and the like of the light-emitting element 101 according to the present embodiment can be specified as follows, for example.

The size, shape, and element analysis of the particles can be implemented by a scanning electron microscope (SEM), a TEM, energy dispersive X-ray spectroscopy (EDS), or a scanning transmission electron microscope (STEM), and components such as Cd, Se, Zn, and S can be detected and confirmed from images.

The elemental analysis of the main components can be implemented by X-ray photoelectron spectroscopy (XPS; atomic %) and chemical analysis (mg/ml), and the components such as Cd, Se, Zn, and S can be detected and confirmed by a spectrum waveform.

The ligand 105 can be detected by TD-GC/MS (thermal desorption—gas chromatography/mass spectrometer) and confirmed by a spectrum waveform.

As for the bonding state of the particle surface, the bonding state of Cd can be detected by XPS, and trace components of CdS and SO can be detected by TOF-SIMS.

Organic impurities in the dispersion liquid can be detected by GC/MS (gas chromatography/mass spectrometry) and LC/MS (liquid chromatography/mass spectrometry) for hydrocarbons, alkylamides, fatty acid esters, alkylphosphines, and alkylamines, and confirmed by a spectral waveform.

The particle size distribution of Cd in the dispersion liquid can be detected by SP-ICP-MS (single particle inductively coupled plasma mass spectrometry).

The light absorption properties of the dispersion liquid can be analyzed by a spectrophotometer.

According to the present embodiment, it is possible to provide a light-emitting element, a method for manufacturing a quantum dot colloidal solution, a method for manufacturing a light-emitting element, and a quantum dot colloidal solution that can improve luminous efficiency while inactivating defects on the surface of the quantum dots 103 and facilitate dispersion of the quantum dots 103 in a solvent for forming the light-emitting layer 102.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1-26. (canceled)

27. A light-emitting element comprising:
a light-emitting layer,
wherein the light-emitting layer includes
a quantum dot,
a halogen element, and
a coordination compound that can coordinate to the quantum dot,
the coordination compound includes a compound having one or more and n or less (where n is a plural number) carbon-hydrogen bonds, or a compound having n chain structures with different elements bonded at any two coordination positions of an element that can substantially have a coordination number of four or greater, and
a mass ratio between the coordination compound and the quantum dot is 0.5 or less.

28. The light-emitting element according to claim 27,
wherein the halogen element is present at or near a surface of the quantum dot.

29. The light-emitting element according to claim 27,
wherein the halogen element has a density from 10¹⁵ cm⁻³ to 10²⁰ cm⁻³.

30. The light-emitting element according to claim 28,
wherein the quantum dot includes a core and a shell formed around the core, and
a distance between the halogen element and the surface of the quantum dot is equal to or less than a distance corresponding to a thickness of the shell.

31. The light-emitting element according to claim 27, further comprising:
a first charge transport layer in contact with the light-emitting layer; and
a second charge transport layer formed on a side of the light-emitting layer opposite to the first charge transport layer,
wherein the light-emitting layer, on a side facing the second charge transport layer, is adjacent to the second charge transport layer with an insulating material interposed between the light-emitting layer and the second charge transport layer.

32. The light-emitting element according to claim 27,
wherein the coordination compound includes a compound having three or more carbon-hydrogen bonds or a compound having three or more chain structures.

33. The light-emitting element according to claim 31,
wherein the first charge transport layer is a hole transport layer configured to transport holes to the light-emitting layer, and
the second charge transport layer is an electron transport layer configured to transport electrons to the light-emitting layer.

34. The light-emitting element according to claim 27,
wherein the halogen element includes F.

35. The light-emitting element according to claim 27,
wherein the halogen element includes at least one of Cl, Br, or I.

36. The light-emitting element according to claim 27,
wherein the coordination compound includes an inorganic compound, an organic compound, or a perfluoro compound.

37. The light-emitting element according to claim 31, further comprising:
an insulating layer formed between the light-emitting layer and the second charge transport layer.

38. The light-emitting element according to claim 37,
wherein the insulating layer is amorphous and includes at least one of a glass-based material, a tetrafluoroethylene-based material, or a silicone-based material.

39. The light-emitting element according to claim 37,
wherein the insulating layer has a light transmittance of 80% or greater in a visible light region.

40. The light-emitting element according to claim 37,
wherein the insulating layer includes an ether-based, perfluoro-based, or hydrocarbon-based solvent.

41. The light-emitting element according to claim 37,
wherein the insulating layer has a thickness of 5 nm or less.

42. A method for manufacturing a quantum dot colloidal solution, the method comprising:
adding a halogen element at or near a surface of a quantum dot;
causing a coordination compound to coordinate to the surface of the quantum dot, with a mass ratio between the coordination compound and the quantum dot being 0.5 or less; and
dispersing the quantum dot with the halogen element added and the coordination compound coordinated into a solvent to obtain a quantum dot colloidal solution.

43. A method for manufacturing a light-emitting element, the method comprising:
forming a quantum dot layer on a first charge transport layer by using a quantum dot colloidal solution manufactured by the method for manufacturing a quantum dot colloidal solution according to claim 42;
removing an excess ligand by applying a solvent to the quantum dot layer after the forming the quantum dot layer; and
performing heat treatment on the quantum dot layer with the excess ligand removed.

44. A quantum dot colloidal solution comprising:
a quantum dot;
a halogen element;
a coordination compound that can coordinate to the quantum dot; and
a solvent in which the quantum dot, the halogen element, and the coordination compound are dispersed,
wherein the coordination compound includes a compound having one or more and n or less (where n is a plural number) carbon-hydrogen bonds, or a compound having n chain structures with different elements bonded at any two coordination positions of an element that can substantially have a coordination number of four or greater, and
a mass ratio between the coordination compound and the quantum dot is 0.5 or less.

45. The quantum dot colloidal solution according to claim 44,
wherein the halogen element is present at or near a surface of the quantum dot.

46. The quantum dot colloidal solution according to claim 44,
wherein the halogen element has a density from 10¹⁵ cm⁻³ to 10²⁰ cm⁻³.
